(19) United States
(12) Patent Application Publication
(10) Pub. No.: US 2021/0263412 A1
(43) Pub. Date: Aug. 26, 2021

(54) RESIST COMPOSITION FOR FORMING THICK-FILM RESIST FILM, THICK-FILM RESIST LAMINATE, AND RESIST PATTERN FORMING METHOD

(71) Applicant: TOKYO OHKA KOGYO CO., LTD., Kawasaki-shi (JP)

(72) Inventors: Eun-Sol JO, Incheon (KR); Yoshiaki OHNO, Incheon (KR); Dae-cheol YU, Incheon (KR)

(21) Appl. No.: 17/169,959

(22) Filed: Feb. 8, 2021

(30) Foreign Application Priority Data
Feb. 20, 2020 (KR) 10-2020-0021155

(51) Int. Cl. G03F 7/004; G03F 7/039; G03F 7/09; G03F 7/32

(52) U.S. Cl. CPC G03F 7/0045; G03F 7/32; G03F 7/09; G03F 7/0397

(57) ABSTRACT

A resist composition including a base material component whose solubility in a developing solution is changed due to an action of an acid, an acid generator component which generates an acid upon light exposure, an acid diffusion control agent component, and a vinyl group-containing compound represented by Formula (e-1), in which the base material component has a mass average molecular weight of 8000 to 18000, and the resist composition has a solid content concentration of 25% by mass or greater (in the formulae, R²⁷ represents a linear or branched alkylene group having 1 to 10 carbon atoms or a group represented by Formula (e-2), each R^{28′}s independently represent a linear or branched alkylene group having 1 to 10 carbon atoms, the alkylene group may have an ether bond in a main chain, and each c's independently represent 0 or 1)

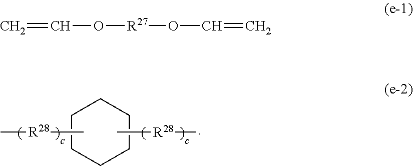

### BACKGROUND OF THE INVENTION

### Field of the Invention

The present invention relates to a resist composition for forming a thick-film resist film, a thick-film resist laminate, and a resist pattern forming method.

### Description of Related Art

In photolithography techniques, for example, a step of forming a resist pattern having a predetermined shape on a resist film is performed by forming a resist film formed of a resist composition on a substrate, performing selective exposure on the resist film to radiation such as light or electron beams through a photomask on which a predetermined pattern has been formed, and performing a developing treatment. A resist composition whose characteristic is changed such that the exposed portion is dissolved in a developing solution is referred to as a positive tone, and a resist composition whose characteristic is changed such that the exposed portion is not dissolved in a developing solution is referred to as a negative tone.

In recent years, in manufacture of semiconductor elements and liquid crystal display elements, advances in lithography techniques have led to rapid progress in the field of miniaturization. The miniaturization means typically involves shortening the wavelength of exposure light. Specifically, ultraviolet rays typified by g-line and i-line have been used in the related art, but nowadays introduction of KrF excimer lasers (248 nm) and ArF excimer lasers (193 nm) has started. Further, examination has also been conducted on F₂ excimer lasers (157 nm), extreme ultraviolet rays (EUV), electron beams, X rays, and the like which have wavelengths shorter than the wavelengths of these excimer lasers.

Further, resist materials are required to have a high resolution in order to reproduce patterns with minute dimensions. As a resist material, a chemically amplified resist composition which contains a base material and an acid generator that generates an acid upon light exposure has been used. For example, a positive-tone chemically amplified resist contains a base material component whose alkali solubility is increased due to an action of an acid and an acid generator component that generates an acid upon light exposure. Further, in a case where an acid is generated from the acid generator upon light exposure in a case of formation of a resist pattern, an exposed portion is alkali-soluble.

As the base material component of a chemically amplified positive-tone resist composition, a base material in which a hydroxyl group of a polyhydroxystyrene (PHS)-based base material is protected by an acid dissociable dissolution inhibition group or a base material in which a carboxy group of a base material (acrylic resin) having a constitutional unit derived from (meth)acrylic acid in a main chain is protected by an acid dissociable dissolution inhibition group has typically been used (see, for example, Japanese Unexamined Patent Application, First Publication No. 2007-206425).

A resist film formed by using a resist composition in the manufacture of a semiconductor element and the like is typically a thin film having a film thickness of approximately 100 to 800 nm, but the resist composition is also used to form a thick-film resist film which has a film thickness greater than that of the thin film, for example, a film thickness of 1 m or greater.

### CITATION LIST

### Patent Document

[Patent Document 1] Japanese Unexamined Patent Application, First Publication No. 2007-206425

### SUMMARY OF THE INVENTION

In a case where a pattern is formed by using a resist composition for forming a thick-film resist film which has been used in the related art as described in Japanese Unexamined Patent Application, First Publication No. 2007-206425, there is a problem in that the viscosity of the resist composition is unlikely to be lowered because cracks occur in the formed pattern and the resist composition contains a base material having a large molecular weight.

The present invention has been made in consideration of the above-described circumstances, and an object thereof is to provide a resist composition for forming a thick-film resist film which has excellent crack resistance and a low viscosity, a thick-film resist laminate, and a resist pattern forming method.

As a result of examination repeatedly conducted by the present inventors, it was found that the above-described problem can be solved by allowing the resist composition for forming a thick-film resist film to contain a specific vinyl group-containing compound and a low-molecular-weight base material and limiting the solid content concentration of the composition, thereby completing the present invention.

According to a first aspect of the present invention, there is provided a resist composition which generates an acid upon light exposure and whose solubility in a developing solution is changed due to an action of an acid, the resist composition including: a base material component (A) whose solubility in a developing solution is changed due to an action of an acid; an acid generator component (B) which generates an acid upon light exposure; an acid diffusion control agent component (D); and a vinyl group-containing compound (E) represented by Formula (e-1), in which the base material component (A) has a mass average molecular weight of 8000 to 18000, and the resist composition has a solid content concentration of 25% by mass or greater.

[Chemical Formula 1]

CH₂═CH—O—R²⁷—O—CH═CH₂ (e-1)

[In the formula, R²⁷ represents a linear or branched alkylene group having 1 to 10 carbon atoms or a group represented by Formula (e-2). R²⁷ may have a substituent and may also have an ether bond in a main chain.]

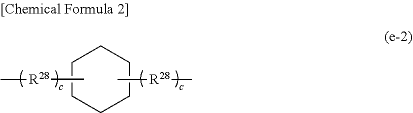

[In the formula, R²⁸'s each independently represent a linear or branched alkylene group having 1 to 10 carbon atoms which may have a substituent, and the alkylene group may have an ether bond in a main chain. c's each independently represent 0 or 1.]

According to a second aspect of the present invention, there is provided a resist laminate including a support; and a resist film formed of the resist composition according to the first aspect laminated on the support, in which the resist film has a film thickness of 8 to 18 μm.

According to a third aspect of the present invention, there is provided a resist pattern forming method including: a step of forming a resist film having a film thickness of 8 to 18 μm using the resist composition according to the first aspect, on a support; a step of selectively exposing the resist film; and a step of performing alkali development on the exposed resist film to form a resist pattern.

According to the present invention, it is possible to provide a resist composition for forming a thick-film resist film having excellent crack resistance and a low viscosity, a thick-film resist laminate, and a resist pattern forming method, by allowing the resist composition to contain a low-molecular-weight base material and a specific vinyl group-containing compound and setting the solid content concentration of the resist composition to be in a specific range.

### BRIEF DESCRIPTION OF THE DRAWINGS

FIG. 1 shows a result of forming a resist pattern formed by using a resist composition of Example 1 in a CD-SEM image.

FIG. 2 shows a result of forming a resist pattern formed by using a resist composition of Comparative Example 2 in a CD-SEM image.

### DETAILED DESCRIPTION OF THE INVENTION

In the present specification and the appended claims, the “constitutional unit” indicates a monomer unit constituting a base material component (polymer compound).

The concept of the “hydroxystyrene” includes hydroxystyrene in a narrow sense, those obtained by substituting the hydrogen atom at the a-position of the hydroxystyrene in a narrow sense with another substituent such as a halogen atom, an alkyl group, or a halogenated alkyl group, and derivatives thereof. The “constitutional unit derived from hydroxystyrene” indicates a constitutional unit that is formed by cleavage of an ethylenic double bond of hydroxystyrene. Further, the “a-position (the carbon atom at the a-position)” of the constitutional unit derived from hydroxystyrene is a carbon atom to which a benzene ring is bonded, unless otherwise specified.

The “constitutional unit derived from acrylic acid ester” indicates a constitutional unit that is formed by cleavage of an ethylenic double bond of acrylic acid ester. The concept of the “acrylic acid ester” includes both acrylic acid ester in which a hydrogen atom is bonded to a carbon atom at the a-position and acrylic acid ester in which a substituent (an atom or a group other than a hydrogen atom) is bonded to the a-position. Examples of the substituent include a halogen atom such as a fluorine atom, an alkyl group, and a halogenated alkyl group. Further, the a-position (the carbon atom at the a-position) of the constitutional unit derived from acrylic acid ester indicates the carbon atom to which a carbonyl group is bonded, unless otherwise specified.

The “(meth)acrylic acid” indicates one or both methacrylic acid and acrylic acid.

The “alkyl group” includes a linear, branched, or cyclic monovalent saturated hydrocarbon group unless otherwise specified.

The “lower alkyl group” is an alkyl group having 1 to 5 carbon atoms. The term “light exposure” is a general concept for irradiation with radiation and irradiation with electron beams.

<<Resist Composition for Forming Thick-Film Resist Film>>

A resist composition for forming a thick-film resist film according to the present invention is a resist composition which generates an acid upon light exposure and whose solubility in a developing solution is changed due to an action of an acid, the resist composition including: a base material component (A) whose solubility in a developing solution is changed due to an action of an acid, an acid generator component (B) which generates an acid upon light exposure, an acid diffusion control agent component (D), and a vinyl group-containing compound (E) represented by Formula (e-1), in which the base material component (A) has a mass average molecular weight of 8000 to 18000, and the resist composition has a solid content concentration of 25% by mass or greater.

[Chemical Formula 3]

CH₂═CH—O—R²⁷—O—CH═CH₂ (e-1)

[In the formula, R²⁷ represents a linear or branched alkylene group having 1 to 10 carbon atoms or a group represented by Formula (e-2). R²⁷ may have a substituent and may also have an ether bond in a main chain.]

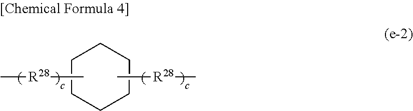

[In the formula, R²⁸'s each independently represent a linear or branched alkylene group having 1 to 10 carbon atoms which may have a substituent, and the alkylene group may have an ether bond in a main chain. c's each independently represent 0 or 1.]

<Base Material Component (A)>

In the present invention, the resist composition for forming a thick-film resist film contains a resin (A) (hereinafter, also referred to as a “component (A)”) whose solubility in a developing solution is changed due to an action of an acid. The component (A) of the present invention is not particularly limited as long as the component is soluble in an organic solvent (S) described below and can be used in a photolithography step. In a case where the base material whose solubility in a developing solution can be changed due to an action of an acid and the acid generator component (B) that generates an acid due to an action of an acid are blended with the resist composition for forming a thick-film resist film, the film to be formed is selectively exposed, and thus the exposed portion or the unexposed portion of the film can be selectively solubilized in a developing solution. In this case, a pattern having a desired shape can be formed by bringing the selectively exposed film into contact with the developing solution to remove the exposed portion or the unexposed portion.

It is preferable that the component (A) has a constitutional unit (a1) derived from hydroxystyrene.

Polymer Compound (A1)

(Constitutional Unit (a1))

The constitutional unit (a1) is a constitutional unit derived from hydroxystyrene. In a case where the resist composition for forming a resist film contains the polymer compound (A1) having the constitutional unit (a1) and the polymer compound (A1) has a mass average molecular weight of 8000 to 18000, the resist composition can have a low viscosity and is easily handled. Further, in a case where the component (A) has the constitutional unit (a1), the dry etching resistance is improved.

Examples of the constitutional unit (a1) include a constitutional unit represented by Formula (a1-1).

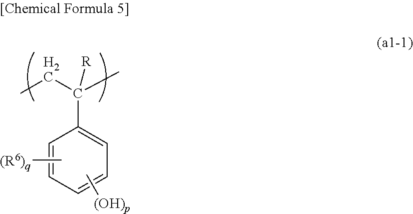

[In the formula, R represents a hydrogen atom, a lower alkyl group having 1 to 5 carbon atoms, a halogen atom, or a halogenated lower alkyl group having 1 to 5 carbon atoms, R⁶ represents a lower alkyl group having 1 to 5 carbon atoms, p represents an integer of 1 to 3, and q represents an integer of 0 to 2.]

In Formula (a1-1), R represents a hydrogen atom, a lower alkyl group, a halogen atom, or a halogenated lower alkyl group.

The lower alkyl group as R is an alkyl group having 1 to 5 carbon atoms and preferably a linear or branched alkyl group, and examples thereof include a methyl group, an ethyl group, a propyl group, an isopropyl group, an n-butyl group, an isobutyl group, a tert-butyl group, a pentyl group, an isopentyl group, and a neopentyl group. From the industrial viewpoint, a methyl group is preferable.

Examples of the halogen atom include a fluorine atom, a chlorine atom, a bromine atom, and an iodine atom. Among these, a fluorine atom is particularly preferable.

The halogenated lower alkyl group is a group in which some or all hydrogen atoms of the lower alkyl group having 1 to 5 carbon atoms are substituted with halogen atoms. In the present invention, it is preferable that all hydrogen atoms are halogenated. As the halogenated lower alkyl group, a linear or branched halogenated lower alkyl group is preferable, particularly a fluorinated lower alkyl group such as a trifluoromethyl group, a pentafluoroethyl group, a heptafluoropropyl group, or a nonafluorobutyl group is more preferable, and a trifluoromethyl group (—CF₃) is still more preferable.

R represents preferably a hydrogen atom or a methyl group and more preferably a hydrogen atom.

Examples of the lower alkyl group having 1 to 5 carbon atoms as R⁶ include the same groups as those for the lower alkyl group as R.

q represents an integer of 0 to 2. Among these, q represents preferably 0 or 1 and particularly preferably 0 from the industrial viewpoint.

The substitution position of R⁶ may be any of the o-position, the m-position, and the p-position in a case where q represents 1. Further, in a case where q represents 2, optional substitution positions can be combined.

p represents an integer of 1 to 3 and preferably 1.

In a case where p represents 1, the substitution position of the hydroxyl group may be any of the o-position, the m-position, and the p-position, but is preferably the p-position from the viewpoints of the availability and low cost. Further, in a case where p represents 2 or 3, optional substitution positions can be combined.

The constitutional unit (a1) can be used alone or in the form of a mixture of two or more kinds thereof.

The proportion of the constitutional unit (a1) in the polymer compound (A1) is preferably in a range of 10% to 95% by mole, more preferably in a range of 20% to 85% by mole, still more preferably in a range of 30% to 80% by mole, and particularly preferably in a range of 60% to 70% by mole with respect to the total amount of all constitutional units constituting the polymer compound (A1). In a case where the proportion thereof is in the above-described range, appropriate alkali solubility can be obtained, and the balance between the constitutional unit (a1) and other constitutional units is satisfactory.

(Constitutional Unit (a2))

The constitutional unit (a2) is a constitutional unit derived from acrylic acid ester containing an acid dissociable dissolution inhibition group.

Examples of the constitutional unit (a2) include a constitutional unit represented by Formula (a2-1).

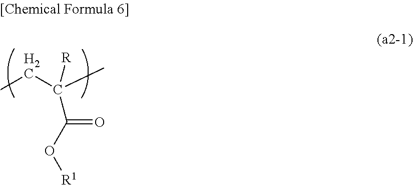

[In the formula, R has the same definition as that for R in Formula (a1-1), and R¹ represents an acid dissociable dissolution inhibition group or an organic group containing an acid dissociable dissolution inhibition group.]

Here, the “acid dissociable dissolution inhibition group” indicates a group that is dissociated due to an acid in a case of generation of the acid from the component (B) upon light exposure and is desorbed from the component (A) after the light exposure, as described above.

Further, the “organic group containing an acid dissociable dissolution inhibition group” indicates a group formed of an acid dissociable dissolution inhibition group and a group or atom that is not dissociated due to an acid (that is, a group or atom that is not dissociated due to an acid and is still bonded to the component (A) even after dissociation of an acid dissociable dissolution inhibition group).

Hereinafter, the acid dissociable dissolution inhibition group and the organic group containing the acid dissociable dissolution inhibition group may be collectively referred to as an “acid dissociable dissolution inhibition group-containing group”.

The acid dissociable dissolution inhibition group is not particularly limited and can be appropriately selected from, for example, a plurality of groups that have been proposed in base materials for resist compositions for KrF excimer lasers, ArF excimer lasers, and the like and then used. Specific examples thereof include a chain-like tertiary alkoxycarbonyl group and a chain-like tertiary alkoxycarbonylalkyl group which are exemplary examples in the following sections of the acid dissociable dissolution inhibition groups (I) and (II) and the acid dissociable dissolution inhibition group-containing group (IV).

The organic group containing an acid dissociable dissolution inhibition group is not particularly limited and can be appropriately selected from, for example, a plurality of groups that have been proposed in base materials for resist compositions for KrF excimer lasers, ArF excimer lasers, and the like and then used. Specific examples thereof include the organic group containing the acid dissociable dissolution inhibition group which is an exemplary example described above. For example, as an organic group containing an acid dissociable dissolution inhibition group (II), an organic group (III) containing an acid dissociable dissolution inhibition group described below is an exemplary example.

Acid Dissociable Dissolution Inhibition Group (I)

The acid dissociable dissolution inhibition group (I) is a chain-like or cyclic tertiary alkyl group. The chain-like tertiary alkyl group has preferably 4 to 10 carbon atoms and more preferably 4 to 8 carbon atoms. More specific examples of the chain-like tertiary alkyl group include a tert-butyl group and a tert-amyl group.

The cyclic tertiary alkyl group is a monocyclic or polycyclic monovalent saturated hydrocarbon group having a tertiary carbon atom on the ring. The cyclic tertiary alkyl group has preferably 4 to 12 carbon atoms and more preferably 5 to 10 carbon atoms. More specifically examples of the cyclic tertiary alkyl group include a 1-methylcyclopentyl group, a 1-ethylcyclopentyl group, a 1-methylcyclohexyl group, a 1-ethylcyclohexyl group, a 2-methyl-2-adamantyl group, and a 2-ethyl-2-adamantyl group.

As the acid dissociable dissolution inhibition group (I), from the viewpoint that the effect of the present invention, that is, the effect of forming a thick-film resist pattern having a satisfactory shape is excellent, a chain-like tertiary alkyl group is preferable, and a tert-butyl group is particularly preferable.

Acid Dissociable Dissolution Inhibition Group (II)

The acid dissociable dissolution inhibition group (II) is a group represented by Formula (II).

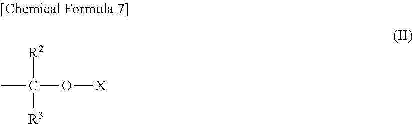

[In the formula, X represents an aliphatic cyclic group, an aromatic cyclic hydrocarbon group, or a lower alkyl group having 1 to 5 carbon atoms, R² represents a hydrogen atom or a lower alkyl group having 1 to 5 carbon atoms, X and R² each independently represent an alkylene groups having 1 to 5 carbon atoms, the terminal of X and the terminal of R² may be bonded to each other, and R³ represents a lower alkyl group having 1 to 5 carbon atoms or a hydrogen atom.]

In Formula (II), X represents an aliphatic cyclic group, an aromatic cyclic hydrocarbon group, or a lower alkyl group having 1 to 5 carbon atoms.

Here, in the present specification and the appended claims, the term “aliphatic” is a relative concept used in relation to the term “aromatic” and is defined as a group or compound that has no aromaticity. The “aliphatic cyclic group” indicates a monocyclic group or a polycyclic group having no aromaticity, and may be saturated or unsaturated. In general, it is preferable that the aliphatic cyclic group is saturated.

The aliphatic cyclic group as X is a monovalent aliphatic cyclic group. The aliphatic cyclic group can be appropriately selected from, for example, a plurality of groups that have been proposed in ArF resists of the related art and then used. Specific examples of the aliphatic cyclic group include an aliphatic monocyclic group having 5 to 7 carbon atoms and an aliphatic polycyclic group having 10 to 16 carbon atoms. Examples of the aliphatic monocyclic group having 5 to 7 carbon atoms include a group in which one hydrogen atom has been removed from a monocycloalkane, and specific examples thereof include a group in which one hydrogen atom has been removed from cyclopentane, cyclohexane, or the like. Examples of the aliphatic polycyclic group having 10 to 16 carbon atoms include groups in which one hydrogen atom has been removed from a bicycloalkane, tricycloalkane, tetracycloalkane, or the like. Specific examples thereof include groups in which two or more hydrogen atoms have been removed from a polycycloalkane such as adamantane, norbornane, isobornane, tricyclodecane, or tetracyclododecane. Among these, an adamantyl group, a norbornyl group, and a tetracyclododecanyl group are preferable from the industrial viewpoint, and an adamantyl group is particularly preferable.

Examples of the aromatic cyclic hydrocarbon group as X include an aromatic polycyclic group having 10 to 16 carbon atoms. Specific examples thereof include a group in which one hydrogen atom has been removed from naphthalene, anthracene, phenanthrene, pyrene, or the like. Specific examples thereof include a 1-naphthyl group, a 2-naphthyl group, a 1-anthracenyl group, a 2-anthracenyl group, a 1-phenanthryl group, a 2-phenanthryl group, a 3-phenanthryl group, and a 1-pyrenyl group. Among these, a 2-naphthyl group is particularly preferable from the industrial viewpoint.

Examples of the lower alkyl group as X include the same groups as those for the lower alkyl group as R in Formula (a1-1). Among these, a methyl group or an ethyl group is more preferable, and an ethyl group is still more preferable.

In Formula (II), examples of the lower alkyl group as R² include the same groups as those for the lower alkyl group as R in Formula (a1-1). Among these, from the industrial viewpoint, a methyl group or an ethyl group is preferable, and a methyl group is particularly preferable.

R³ represents a lower alkyl group or a hydrogen atom. Examples of the lower alkyl group as R³ include the same groups as those for the lower alkyl group as R². From the industrial viewpoint, it is preferable that R³ represents a hydrogen atom. Further, in Formula (II), X and R² each independently represent an alkylene group having 1 to 5 carbon atoms, and the terminal of X and the terminal of R² may be bonded to each other.

In this case, in Formula (II), a cyclic group is formed by R², X, an oxygen atom to which A is bonded, and a carbon atom to which the oxygen atom and R² are bonded. As the cyclic group, a 4- to 7-membered ring is preferable, and a 4- to 6-membered ring is more preferable. Specific examples of the cyclic group include a tetrahydropyranyl group and a tetrahydrofuranyl group.

As the acid dissociable dissolution inhibition group (II), from the viewpoint that the effect of the present invention, that is, the effect of forming a thick-film resist pattern having a satisfactory shape is excellent, it is preferable that R³ represents a hydrogen atom and R² represents a hydrogen atom or a lower alkyl group.

Specific examples thereof include a group in which X represents a lower alkyl group, that is, a 1-alkoxyalkyl group such as a 1-methoxyethyl group, a 1-ethoxyethyl group, a 1-iso-propoxyethyl group, a 1-n-butoxyethyl group, a 1-tert-butoxyethyl group, a methoxymethyl group, an ethoxymethyl group, an iso-propoxymethyl group, an n-butoxymethyl group, and a tert-butoxymethyl group.

Further, examples of the group in which X represents an aliphatic cyclic group include a 1-cyclohexyloxyethyl group, a 1-(2-adamantyl)oxymethyl group, and a 1-(1-adamantyl)oxyethyl group represented by Formula (II-a).

Examples of the group in which X represents an aromatic cyclic hydrocarbon group include a 1-(2-naphthyl)oxyethyl group represented by Formula (II-b).

Among these, a 1-ethoxyethyl group is particularly preferable.

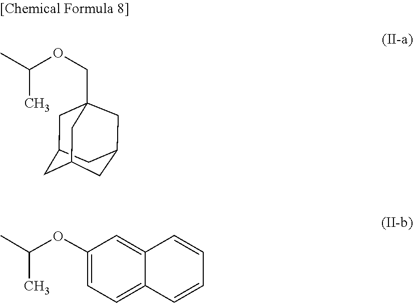

Organic Group (III) Containing Acid Dissociable Dissolution Inhibition Group

The organic group (III) containing an acid dissociable dissolution inhibition group is a group represented by Formula (III). In the organic group (III) having such a structure, in a case where an acid is generated from the component (B) upon light exposure, the bond between the oxygen atom bonded to Y and the carbon atom to which R⁴ and R⁵ are bonded is cut off due to the acid so that —C(R⁴)(R⁵)—OX′ is dissociated.

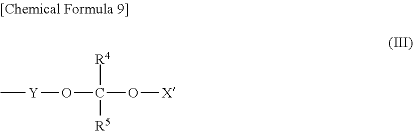

[In the formula, X′ represents an aliphatic cyclic group, an aromatic cyclic hydrocarbon group, or a lower alkyl group having 1 to 5 carbon atoms, R⁴ represents a hydrogen atom or a lower alkyl group having 1 to 5 carbon atoms, X′ and R⁴ each independently represent an alkylene group having 1 to 5 carbon atoms, the terminal of X′ and the terminal of R⁴ may be bonded to each other, R⁵ represents a lower alkyl group having 1 to 5 carbon atoms or a hydrogen atom, and Y represents an aliphatic cyclic group.]

In Formula (III), examples of the aliphatic cyclic group, the aromatic cyclic hydrocarbon group, or the lower alkyl group having 1 to 5 carbon atoms as X′ include the same groups as those for the aliphatic cyclic group, the aromatic cyclic hydrocarbon group, or the lower alkyl group having 1 to 5 carbon atoms as X in Formula (II).

Examples of the lower alkyl group having 1 to 5 carbon atoms as R⁴ include the same groups as those for the lower alkyl group having 1 to 5 carbon atoms as R².

Examples of the lower alkyl group having 1 to 5 carbon atoms as R⁵ include the same groups as those for the lower alkyl group having 1 to 5 carbon atoms as R³.

Examples of the aliphatic cyclic group as Y include a group in which one hydrogen atom has been further removed from the aliphatic cyclic group as X.

Acid dissociable dissolution inhibition group-containing group (IV) The acid dissociable dissolution inhibition group-containing group (IV) is an acid dissociable dissolution inhibition group-containing group that is not classified into any of the acid dissociable dissolution inhibition groups (I) and (II) and the organic group (III) containing an acid dissociable dissolution inhibition group (hereinafter, these are also collectively referred to as “acid dissociable dissolution inhibition groups and the like (I) to (III)”)

As the acid dissociable dissolution inhibition group-containing group (IV), an optional acid dissociable dissolution inhibition group-containing group that is not classified into any of the acid dissociable dissolution inhibition groups and the like (I) to (III) among known acid dissociable dissolution inhibition group-containing groups of the related art can be used.

Specific examples of the acid dissociable dissolution inhibition group that is not classified into any of the acid dissociable dissolution inhibition groups and the like (I) to (III) include a chain-like tertiary alkoxycarbonyl group and a chain-like tertiary alkoxycarbonyl group.

The chain-like tertiary alkoxycarbonyl group has preferably 4 to 10 carbon atoms and more preferably 4 to 8 carbon atoms. Specific examples of the chain-like tertiary alkoxycarbonyl group include a tert-butoxycarbonyl group and a tert-amyloxycarbonyl group.

The chain-like tertiary alkoxycarbonylalkyl group has preferably 4 to 10 carbon atoms and more preferably 4 to 8 carbon atoms. Specific examples of the chain-like tertiary alkoxycarbonylalkyl group include a tert-butoxycarbonylmethyl group and a tert-amyloxycarbonylmethyl group.

As the acid dissociable dissolution inhibition group-containing group in the constitutional unit (a2), from the viewpoint that the effect of the present invention, that is, the effect of forming a thick-film resist pattern having a satisfactory shape is excellent, the constitutional unit (a2) contains preferably at least one selected from the group consisting of the acid dissociable dissolution inhibition groups and the like (I) to (III) and particularly preferably the acid dissociable dissolution inhibition group (I).

The constitutional unit (a2) can be used alone or in the form of a mixture of two or more kinds thereof.

The proportion of the constitutional unit (a2) in the polymer compound (A1) is preferably in a range of 1% to 80% by mole, more preferably in a range of 1% to 60% by mole, still more preferably in a range of 2% to 50% by mole, particularly preferably in a range of 5% to 40% by mole, and most preferably in a range of 5% to 35% by mole with respect to the total amount of all constitutional units constituting the polymer compound (A1). In a case where the proportion thereof is set to be greater than or equal to the above-described lower limit, a pattern using the resist composition can be obtained. Further, in a case where the proportion thereof is set to be lower than or equal to the above-described upper limit, the balance between the constitutional unit (a2) and other constitutional units is satisfactory.

[Other Constitutional Units]

The polymer compound (A1) may further have, in addition to the constitutional units (a1) and (a2), constitutional units other than the constitutional units (a1) and (a2). Specific examples of other constitutional units include the following constitutional units (a3) to (a5).

(Constitutional unit (a3)) The constitutional unit (a3) is a constitutional unit derived from styrene. In the present invention, it is preferable that the polymer compound (A1) has the constitutional unit (a3). By allowing the polymer compound (A1) to have the constitutional unit (a3) and adjusting the content thereof, the solubility of the polymer compound (A1) in an alkali developing solution can be adjusted, and thus the alkali solubility of the thick-film resist film can be controlled and the shape can be further improved.

Here, the concept of “styrene” includes styrene in a narrow sense, those obtained by substituting the hydrogen atom at the a-position of the styrene in a narrow sense with another substituent such as a halogen atom, an alkyl group, or a halogenated alkyl group, and derivatives thereof. The “constitutional unit derived from styrene” indicates a constitutional unit that is formed by cleavage of an ethylenic double bond of styrene. In styrene, the hydrogen atom of the phenyl group may be substituted with a substituent such as a lower alkyl group having 1 to 5 carbon atoms.

Examples of the constitutional unit (a3) include a constitutional unit represented by Formula (a3-1).

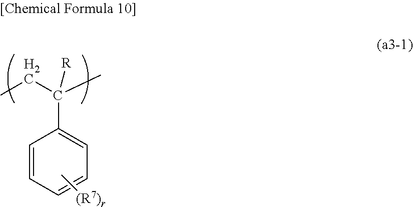

[In the formula, R has the same definition as that for R in Formula (a1-1), R⁷ represents a lower alkyl group having 1 to 5 carbon atoms, and r represents an integer of 0 to 3.]

In Formula (a3-1), examples of each R include the same groups as those for R in Formula (a1-1).

Examples of the lower alkyl group having 1 to 5 carbon atoms as R⁷ include the same groups as those for the lower alkyl group having 1 to 5 carbon atoms as R⁶ in Formula (a1-1). r represents an integer of 0 to 3. Among these, r represents preferably 0 or 1 and particularly preferably 0 from the industrial viewpoint.

The substitution position of R⁷ may be any of the o-position, the m-position, and the p-position in a case where r represents 1 to 3. Further, in a case where r represents 2 or 3, optional substitution positions can be combined.

The constitutional unit (a3) may be used alone or in combination of two or more kinds thereof.

In a case where the polymer compound (A1) has the constitutional unit (a3), the proportion of the constitutional unit (a3) is preferably in a range of 1% to 20% by mole, more preferably in a range of 3% to 15% by mole, and particularly preferably in a range of 5% to 15% by mole with respect to the total amount of all constitutional units constituting the polymer compound (A1). In a case where the proportion thereof is in the above-described range, the effect obtained by allowing the polymer compound (A1) to have the constitutional unit (a3) is high, and the balance between the constitutional unit (a3) and other constitutional units is also satisfactory.

(Constitutional Unit (a4))

A constitutional unit (a4) is a constitutional unit formed by substituting the hydrogen atom of the hydroxyl group in the constitutional unit (a1) with an acid dissociable dissolution inhibition group-containing group. In a case where the polymer compound (A1) has such a constitutional unit (a4), the etching resistance and the resolution are improved.

Examples of the acid dissociable dissolution inhibition group-containing group in the constitutional unit (a4) include the same groups as those which are exemplary examples in the section of the constitutional unit (a2). Among these, the polymer compound (A1) contains preferably at least one selected from the group consisting of the acid dissociable dissolution inhibition groups (I) to (III) from the viewpoint that a thick-film resist pattern having a satisfactory shape can be formed and particularly preferably the acid dissociable dissolution inhibition group (I) or (II).

The constitutional unit (a4) can be used alone or in the form of a mixture of two or more kinds thereof.

In a case where the polymer compound (A1) has the constitutional unit (a4), the proportion of the constitutional unit (a4) in the polymer compound (A1) is preferably in a range of 5% to 50% by mole, more preferably in a range of 5% to 45% by mole, still more preferably in a range of 10% to 40% by mole, and particularly preferably in a range of 15% to 40% by mole with respect to the total amount of all constitutional units constituting the polymer compound (A1). In a case where the proportion thereof is set to be greater than or equal to the above-described lower limit, a thick-film resist pattern having a satisfactory shape can be obtained by blending the constitutional unit (a4) with the polymer compound (A1). Further, in a case where the proportion thereof is set to be less than or equal to the above-described upper limit, the balance between the constitutional unit (a4) and other constitutional units is satisfactory.

(Constitutional Unit (a5))

The constitutional unit (a5) is a constitutional unit derived from acrylic acid ester containing an alcoholic hydroxyl group. In a case where the polymer compound (A1) has such a constitutional unit (a5), a thick-film resist pattern having a satisfactory shape can be formed.

Preferred examples of the constitutional unit (a5) include a constitutional unit containing a chain-like or cyclic alkyl group containing an alcoholic hydroxyl group. That is, it is preferable that the constitutional unit (a5) is a constitutional unit derived from acrylic acid ester containing an alcoholic hydroxyl group-containing chain-like or cyclic alkyl group.

In a case where the constitutional unit (a5) has a constitutional unit derived from acrylic acid ester containing an alcoholic hydroxyl group-containing cyclic alkyl group (hereinafter, also simply referred to as a “constitutional unit containing a hydroxyl group-containing cyclic alkyl group”), the resolution is enhanced, and the etching resistance is also improved.

Further, in a case where the constitutional unit (a5) is a constitutional unit derived from acrylic acid ester containing an alcoholic hydroxyl group-containing chain-like alkyl group (hereinafter, also simply referred to as a “constitutional unit containing a hydroxyl group-containing chain-like alkyl group”), the hydrophilicity of the entire component (A) is enhanced, the affinity for the developing solution is enhanced, and thus the resolution is improved.

“Constitutional unit containing hydroxyl group-containing cyclic alkyl group” Examples of the constitutional unit containing a hydroxyl group-containing cyclic alkyl group include a constitutional unit in which a hydroxyl group-containing cyclic alkyl group is bonded to an ester group [—C(O)O-] of acrylic acid ester. Here, the “hydroxyl group-containing cyclic alkyl group” is a group in which a hydroxyl group is bonded to a cyclic alkyl group.

The number of hydroxyl groups to be bonded to the cyclic alkyl group is, for example, preferably in a range of 1 to 3 and more preferably 1.

The cyclic alkyl group may be monocyclic or polycyclic, but it is preferable that the cyclic alkyl group is a polycyclic group. Further, the number of carbon atoms of the cyclic alkyl group is preferably in a range of 5 to 15.

Specific examples of the cyclic alkyl group include the followings.

Examples of the monocyclic cyclic alkyl group include a group in which one to four hydrogen atoms have been removed from a cycloalkane. More specific examples of the monocyclic cyclic alkyl group include a group in which one to four hydrogen atoms have been removed from cyclopentane or cyclohexane. Among these, a cyclohexyl group is preferable.

Examples of the polycyclic cyclic alkyl group include a group in which one to four hydrogen atoms have been removed from bicycloalkane, tricycloalkane, tetracycloalkane, or the like. Specific examples thereof include a group in which one to four hydrogen atoms have been removed from a polycycloalkane such as adamantane, norbornane, isobornane, tricyclodecane, or tetracyclododecane.

Further, such a cyclic alkyl group can be appropriately selected from, for example, a plurality of groups that have been proposed as those constituting an acid dissociable dissolution inhibition group in a base material for a photoresist composition for an ArF excimer laser process and then used. Among these, from the viewpoint of the industrial availability, a cyclohexyl group, an adamantyl group, a norbornyl group, and a tetracyclododecanyl group are preferable.

Among these exemplified monocyclic groups and polycyclic groups, a cyclohexyl group and an adamantyl group are preferable, and an adamantyl group is particularly preferable.

As a specific example of the constitutional unit containing a hydroxyl group-containing cyclic alkyl group, for example, the constitutional unit (a5-1) represented by Formula (a5-1) is preferable.

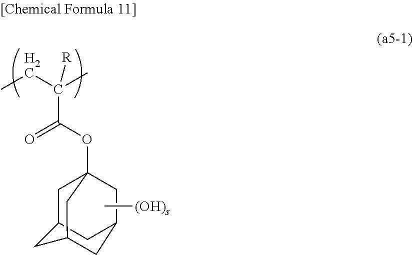

[In the formula, R has the same definition as that for R in Formula (a1-1), and s represents an integer of 1 to 3.]

In Formula (a5-1), examples of R include the same groups as those for R in Formula (a1-1).

s represents an integer of 1 to 3 and most preferably 1.

The bonding position of the hydroxyl group is not particularly limited, but it is preferable that the hydroxyl group is bonded to the 3rd position of the adamantyl group.

“Constitutional unit containing hydroxyl group-containing chain-like alkyl group”

Examples of the constitutional unit containing a hydroxyl group-containing chain-like alkyl group include a constitutional unit in which a chain-like hydroxyalkyl group is bonded to an ester group [C(O)O-] of an acrylic acid ester. Here, the “chain-like hydroxyalkyl group” indicates a group in which some or all hydrogen atoms in a chain-like (linear or branched) alkyl group have been substituted with a hydroxyl group.

As the constitutional unit containing a hydroxyl group-containing chain-like alkyl group, a constitutional unit (a5-2) represented by Formula (a5-2) is particularly preferable.

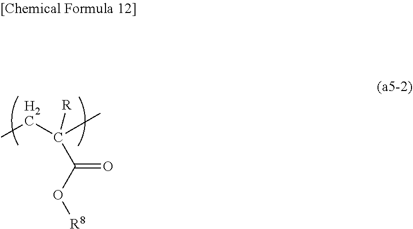

[In the formula, R has the same definition as that for R in Formula (a1-1), and R⁸ represents a chain-like hydroxyalkyl group.]

R in Formula (a5-2) has the same definition as that for R in Formula (a1-1). As the chain-like hydroxyalkyl group as R⁸, a lower hydroxyalkyl group having 1 to 10 carbon atoms is preferable, a lower hydroxyalkyl group having 2 to 8 carbon atoms is more preferable, and a linear lower hydroxyalkyl group having 2 to 4 carbon atoms is still more preferable.

The number of hydroxyl groups in the hydroxyalkyl group and the bonding position thereof are not particularly limited, but the number of hydroxyl groups is typically one, and the terminal of the alkyl group is preferable as the bonding position.

The constitutional unit (a5) can be used alone or in the form of a mixture of two or more kinds thereof.

In a case where the polymer compound (A1) has the constitutional unit (a5), the proportion of the constitutional unit (a5) in the polymer compound (A1) is preferably in a range of 5% to 50% by mole, more preferably in a range of 5% to 45% by mole, still more preferably in a range of 10% to 40% by mole, and particularly preferably in a range of 15% to 40% by mole with respect to the total amount of all constitutional units of the polymer compound (A1). In a case where the proportion thereof is greater than or equal to the above-described lower limit, the effect obtained by allowing the polymer compound (A1) to have the constitutional unit (a5) is high. Further, in a case where the proportion thereof is less than or equal to the above-described upper limit, the balance between the constitutional unit (a5) and other constitutional units is satisfactory.

The polymer compound (A1) may have a constitutional unit (a6) other than the constitutional units (a1) to (a5) as long as the effects of the present invention are not impaired.

The constitutional unit (a6) is not particularly limited as long as the constitutional unit is another constitutional unit that is not classified into any of the above-described constitutional units (a1) to (a5), and a plurality of constitutional units which have been known in the related art as those used in a base material for a resist for an ArF excimer laser or a KrF positive excimer laser (preferably an ArF excimer laser) can be used.

In the present invention, it is preferable that the polymer compound (A1) is a copolymer having at least the constitutional units (a1) and (a2).

Such a copolymer may be a copolymer formed of the constitutional units (a1) and (a2) and may be a copolymer having the constitutional units (a1) and (a2) and further having at least one of the constitutional units (a3), (a4), and (a5). In the present invention, as the copolymer, a binary copolymer (A1-2) formed of the constitutional units (a1) and (a2); a ternary copolymer (A1-3) formed of the constitutional units (a1), (a2), and (a3); a quaternary copolymer (A1-4-1) formed of the constitutional units (a1), (a2), (a3), and (a4); or a quaternary copolymer (A1-4-2) formed of the constitutional units (a1), (a2), (a3), and (a5) is preferable, and a ternary copolymer (A1-3) is particularly preferable.

The proportion of the constitutional unit (a1) in the ternary copolymer (A1-3) is preferably in a range of 10% to 95% by mole, more preferably in a range of 20% to 85% by mole, still more preferably in a range of 30% to 80% by mole, and particularly preferably in a range of 60% to 70% by mole with respect to the total amount of all constitutional units constituting the ternary copolymer (A1-3). The proportion of the constitutional unit (a2) is preferably in a range of 1% to 80% by mole, more preferably in a range of 1% to 60% by mole, particularly preferably in a range of 2% to 50% by mole, and most preferably in a range of 5% to 35% by mole. The proportion of the constitutional unit (a3) is preferably in a range of 1% to 20% by mole, more preferably in a range of 3% to 15% by mole, and particularly preferably in a range of 5% to 15% by mole.

As the polymer compound (A1), a copolymer having three constitutional units represented by Formula (A-11) is particularly preferable.

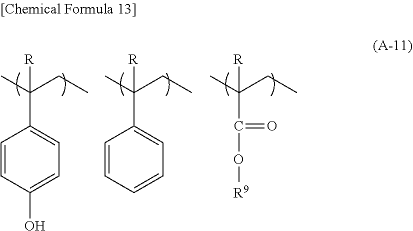

[In the formula, R has the same definition as that for R in Formula (a1-1), and R⁹ represents a tertiary alkyl group having 4 to 12 carbon atoms.]

The polymer compound (A1) can be obtained by polymerizing a monomer, from which each constitutional unit is derived, by performing known radical polymerization using a radical polymerization initiator such as azobisisobutyronitrile (AIBN). As an example thereof, the polymer compound (A1) can be produced by preparing, for example, a monomer in which the hydroxyl group of hydroxystyrene is protected by a protecting group such as an acetyl group and a monomer corresponding to the constitutional unit (a2), copolymerizing these monomers according to a known method, and substituting the protecting group with a hydrogen atom through hydrolysis to obtain the constitutional unit (a1).

The polymer compound (A1) has a mass average molecular weight (Mw; in terms of polystyrene according to gel permeation chromatography (GPC), the same applies hereinafter) of 8000 to 18000.

In a case where the mass average molecular weight of the polymer compound (A1) is 8000 or greater, the effects of improving the heat resistance of the thick-film resist film and improving the etching resistance can be obtained, and the effect of forming a thick-film resist pattern having a satisfactory shape can also be obtained.

In a case where the mass average molecular weight of the polymer compound (A1) is 18000 or less, the viscosity of the resist composition can be lowered.

The mass average molecular weight of the polymer compound (A1) is preferably in a range of 10000 to 15000 and more preferably in a range of 10000 to 13000.

Further, from the viewpoint that the resolution is excellent, it is preferable that the dispersity (Mw/Mn (number average molecular weight)) of the polymer compound (A1) decreases (as the dispersity closes to the monodispersity). Further, the dispersity (Mw/Mn) thereof is preferably in a range of 1.0 to 5.0, more preferably in a range of 1.0 to 3.0, and most preferably in a range of 1.0 to 2.5.

The polymer compound (A1) may be used alone or in combination of two or more kinds thereof.

The proportion of the polymer compound (A1) in the component (A) is preferably in a range of 50% to 100% by mass, more preferably in a range of 80% to 100% by mass, and most preferably 100% by mass from the viewpoint of the effects of the present invention.

In the present invention, the resist composition may contain, as the component (A), a base material typically used as a base material for a chemically amplified positive-tone resist such as a PHS-based resin, an acrylic resin, or the like in addition to the polymer compound (A1), as long as the effects of the present invention are not impaired.

In the resist composition for forming a thick-film resist film of the present invention, the content of the component (A) may be adjusted according to the thickness of the resist film intended to be formed.

<Acid Generator Component (B)>

The resist composition for forming a thick-film resist film of the present invention may further contain an acid generator component (hereinafter, also referred to as a “component (B)”) in addition to the component (A).

The component (B) is not particularly limited, and those which have been proposed as acid generators for resists in the related art can be used.

Examples of such an acid generator include various acid generators, for example, onium salt-based acid generators such as iodonium salts and sulfonium salts; oxime sulfonate-based acid generators; diazomethane-based acid generators such as bisalkyl or bisaryl sulfonyl diazomethanes and poly(bis-sulfonyl)diazomethanes; nitrobenzylsulfonate-based acid generators, iminosulfonate-based acid generators, and disulfone-based acid generators. Among these, it is preferable to use an onium salt-based acid generator.

Examples of the onium salt-based acid generators include a compound represented by Formula (b-1) (hereinafter, also referred to as a “component (b-1)”), a compound represented by Formula (b-2) (hereinafter, also referred to as a “component (b-2)”), and a compound represented by Formula (b-3) (hereinafter, also referred to as a “component (b-3)”).

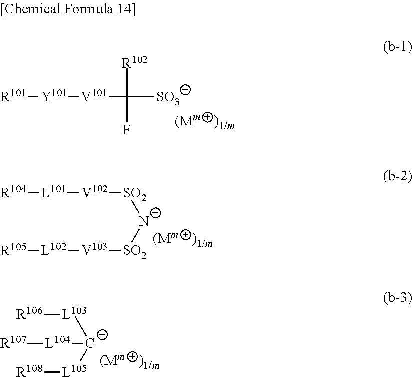

[In the formulae, R¹⁰¹ and R¹⁰⁴ to R¹⁰⁸ each independently represent a halogen atom, a cyclic group which may have a substituent, a chain-like alkyl group which may have a substituent, or a chain-like alkenyl group which may have a substituent. R¹⁰⁴ and R¹⁰⁵ may be bonded to each other to form a ring. R¹⁰² represents a fluorine atom or a fluorinated alkyl group having 1 to 5 carbon atoms. Y¹⁰¹ represents a single bond or a divalent linking group having an oxygen atom. V¹⁰¹ to V¹⁰³ each independently represent a single bond, an alkylene group, or a fluorinated alkylene group. L¹⁰¹ and L¹⁰² each independently represent a single bond or an oxygen atom. L¹⁰³ to L¹⁰⁵ each independently represent a single bond, —CO—, or —SO₂—. m represents an integer of 1 or greater, and M′^{m+} represents an m-valent onium cation.]

{Anion Moiety}

Anion Moiety of Component (b-1)

In Formula (b-1), R¹⁰¹ represents a halogen atom, a cyclic group which may have a substituent, a chain-like alkyl group which may have a substituent, or a chain-like alkenyl group which may have a substituent.

Examples of the halogen atom include a fluorine atom, a chlorine atom, a bromine atom, and an iodine atom. Among these, a fluorine atom is preferable.

Cyclic group which may have substituent:

The cyclic group is preferably a cyclic hydrocarbon group, and the cyclic hydrocarbon group may be an aromatic hydrocarbon group or an aliphatic hydrocarbon group. The aliphatic hydrocarbon group indicates a hydrocarbon group that has no aromaticity. Further, the aliphatic hydrocarbon group may be saturated or unsaturated. In general, it is preferable that the aliphatic hydrocarbon group is saturated.

The aromatic hydrocarbon group as R¹⁰¹ is a hydrocarbon group having an aromatic ring. The aromatic hydrocarbon group has preferably 3 to 30 carbon atoms, more preferably 5 to 30 carbon atoms, still more preferably 5 to 20 carbon atoms, particularly preferably 6 to 15 carbon atoms, and most preferably 6 to 10 carbon atoms. Here, the number of carbon atoms in a substituent is not included in the number of carbon atoms.

Specific examples of the aromatic ring contained in the aromatic hydrocarbon group as R¹⁰¹ include benzene, fluorene, naphthalene, anthracene, phenanthrene, biphenyl, and an aromatic hetero ring in which some carbon atoms constituting these aromatic rings have been substituted with hetero atoms. Examples of the hetero atom in the aromatic hetero rings include an oxygen atom, a sulfur atom, and a nitrogen atom.

Specific examples of the aromatic hydrocarbon group as R^{1′} include a group in which one hydrogen atom has been removed from the aromatic ring (for example, an aryl group such as a phenyl group or a naphthyl group), and a group in which one hydrogen atom in the aromatic ring has been substituted with an alkylene group (for example, an arylalkyl group such as a benzyl group, a phenethyl group, a 1-naphthylmethyl group, a 2-naphthylmethyl group, a 1-naphthylethyl group, or a 2-naphthylethyl group). The alkylene group (the alkyl chain in the arylalkyl group) has preferably 1 to 4 carbon atoms, more preferably 1 or 2 carbon atoms, and still more preferably 1 carbon atom.

Examples of the cyclic aliphatic hydrocarbon group as R¹⁰¹ include an aliphatic hydrocarbon group having a ring in the structure thereof.

Examples of the aliphatic hydrocarbon group having a ring in the structure thereof include an alicyclic hydrocarbon group (a group in which one hydrogen atom has been removed from an aliphatic hydrocarbon ring), a group in which an alicyclic hydrocarbon group is bonded to the terminal of a linear or branched aliphatic hydrocarbon group, and a group in which an alicyclic hydrocarbon group is interposed in a linear or branched aliphatic hydrocarbon group.

The alicyclic hydrocarbon group has preferably 3 to 20 carbon atoms and more preferably 3 to 12 carbon atoms.

The alicyclic hydrocarbon group may be a polycyclic group or a monocyclic group. As the monocyclic alicyclic hydrocarbon group, a group in which one or more hydrogen atoms have been removed from a monocycloalkane is preferable. The number of carbon atoms of the monocycloalkane is preferably in a range of 3 to 6, and specific examples thereof include cyclopentane and cyclohexane. As the polycyclic alicyclic hydrocarbon group, a group in which one or more hydrogen atoms have been removed from a polycycloalkane is preferable, and the number of carbon atoms of the polycycloalkane is preferably in a range of 7 to 30. Among these, a polycycloalkane having a crosslinked ring polycyclic skeleton such as adamantane, norbornane, isobornane, tricyclodecane, or tetracyclododecane; and a polycycloalkane having a fused ring polycyclic skeleton such as a cyclic group having a steroid skeleton are more preferable as the polycycloalkane.

Among these examples, as the cyclic aliphatic hydrocarbon group as R¹⁰¹, a group in which one or more hydrogen atoms have been removed from a monocycloalkane or a polycycloalkane is preferable, a group in which one hydrogen atom has been removed from a polycycloalkane is more preferable, an adamantyl group or a norbornyl group is still more preferable, and an adamantyl group is particularly preferable.

The linear or branched aliphatic hydrocarbon group which may be bonded to the alicyclic hydrocarbon group has preferably 1 to 10 carbon atoms, more preferably 1 to 6 carbon atoms, still more preferably 1 to 4 carbon atoms, and particularly preferably 1 to 3 carbon atoms.

As the linear aliphatic hydrocarbon group, a linear alkylene group is preferable. Specific examples thereof include a methylene group [—CH₂—], an ethylene group [—(CH₂)₂—], a trimethylene group [—(CH₂)₃—], a tetramethylene group [—(CH₂)₄—], and a pentamethylene group [—(CH₂)₅—].

As the branched aliphatic hydrocarbon group, a branched alkylene group is preferable, and specific examples thereof include alkylalkylene groups, for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. As the alkyl group in the alkylalkylene group, a linear alkyl group having 1 to 5 carbon atoms is preferable.

Further, the cyclic hydrocarbon group as R¹⁰¹ may have a hetero atom such as a hetero ring. Specific examples thereof include heterocyclic groups respectively represented by Formulae (r-hr-1) to (r-hr-16). “*” represents a bonding position.

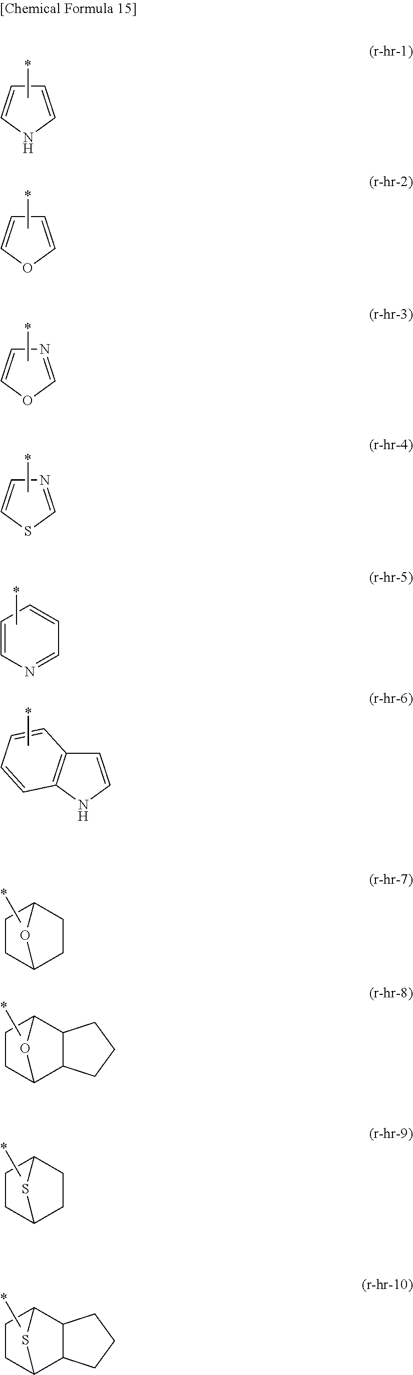

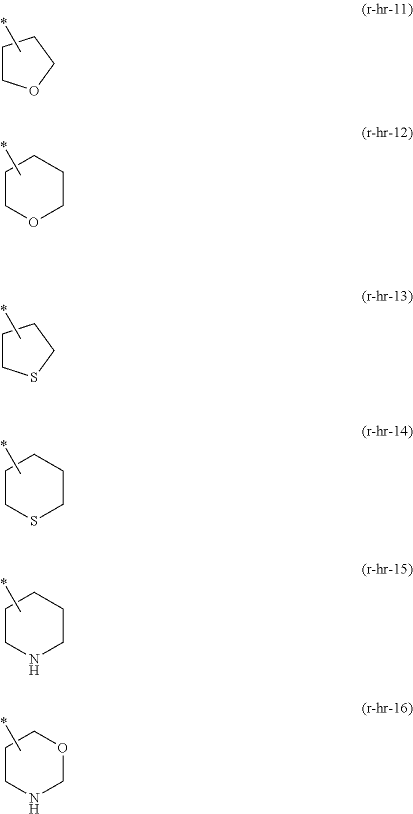

Examples of the substituent for the cyclic group as R¹⁰¹ include an alkyl group, an alkoxy group, a halogen atom, a halogenated alkyl group, a hydroxyl group, a carbonyl group, and a nitro group.

As the alkyl group as the substituent, an alkyl group having 1 to 5 carbon atoms is preferable, and a methyl group, an ethyl group, a propyl group, an n-butyl group, or a tert-butyl group is more preferable.

As the alkoxy group as the substituent, an alkoxy group having 1 to 5 carbon atoms is preferable, a methoxy group, an ethoxy group, an n-propoxy group, an iso-propoxy group, an n-butoxy group, or a tert-butoxy group is more preferable, and a methoxy group or an ethoxy group is still more preferable.

Examples of the halogen atom as the substituent include a fluorine atom, a chlorine atom, a bromine atom, and an iodine atom. Among these, a fluorine atom is preferable.

Example of the halogenated alkyl group as the substituent includes a group in which some or all hydrogen atoms in an alkyl group having 1 to 5 carbon atoms such as a methyl group, an ethyl group, a propyl group, an n-butyl group, or a tert-butyl group have been substituted with the halogen atoms.

The carbonyl group as the substituent is a group that substitutes a methylene group (—CH₂—) constituting the cyclic hydrocarbon group.

Chain-like alkyl group which may have substituent:

The chain-like alkyl group as R¹⁰¹ may be linear or branched.

The linear alkyl group has preferably 1 to 20 carbon atoms, more preferably 1 to 15 carbon atoms, and still more preferably 1 to 10 carbon atoms. Specific examples thereof include a methyl group, an ethyl group, a propyl group, a butyl group, a pentyl group, a hexyl group, a heptyl group, an octyl group, a nonyl group, a decanyl group, an undecyl group, a dodecyl group, a tridecyl group, an isotridecyl group, a tetradecyl group, a pentadecyl group, a hexadecyl group, an isohexadecyl group, a heptadecyl group, an octadecyl group, a nonadecyl group, an icosyl group, a henicosyl group, and a docosyl group.

The branched alkyl group has preferably 3 to 20 carbon atoms, more preferably 3 to 15 carbon atoms, and still more preferably 3 to 10 carbon atoms. Specific examples thereof include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, and a 4-methylpentyl group.

Chain-like alkenyl group which may have substituent:

The chain-like alkenyl group as R¹⁰¹ may be linear or branched, and the number of carbon atoms thereof is preferably in a range of 2 to 10, more preferably in a range of 2 to 5, still more preferably in a range of 2 to 4, and particularly preferably 3. Examples of the linear alkenyl group include a vinyl group, a propenyl group (allyl group), and a butynyl group. Examples of the branched alkenyl group include a 1-methylvinyl group, a 2-methylvinyl group, a 1-methylpropenyl group, and a 2-methylpropenyl group.

Among the examples, as the chain-like alkenyl group, a linear alkenyl group is preferable, a vinyl group or a propenyl group is more preferable, and a vinyl group is particularly preferable.

Examples of the substituent for the chain-like alkyl group or alkenyl group as R¹⁰¹ include an alkoxy group, a halogen atom, a halogenated alkyl group, a hydroxyl group, a carbonyl group, a nitro group, an amino group, and the cyclic group as R¹⁰¹.

Among these, R¹⁰¹ represents preferably a cyclic group which may have a substituent, a chain-like alkyl group which may have a substituent, or a chain-like alkenyl group which may have a substituent, more preferably a cyclic group which may have a substituent, and still more preferably a cyclic hydrocarbon group which may have a substituent from the viewpoint of critical dimension uniformity (CDU).

Among these, a group in which one or more hydrogen atoms have been removed from a phenyl group, a naphthyl group, or a polycycloalkane is preferable, and among these, a group in which one or more hydrogen atoms have been removed from a polycycloalkane is more preferable.

In Formula (b-1), Y¹⁰¹ represents a single bond or a divalent linking group having an oxygen atom and is preferably a divalent linking group having an oxygen atom from the viewpoint of the critical dimension uniformity.

In a case where Y¹⁰¹ represents a divalent linking group having an oxygen atom, Y¹⁰¹ may have an atom other than the oxygen atom. Examples of the atom other than the oxygen atom include a carbon atom, a hydrogen atom, a sulfur atom, and a nitrogen atom.

Examples of the divalent linking group having an oxygen atom include a non-hydrocarbon oxygen atom-containing linking group such as an oxygen atom (an ether bond: —O—), an ester bond (—C(═O)—O—), an oxycarbonyl group (—O—C(═O)—), an amide bond (—C(═O)—NH—), a carbonyl group (—C(═O)—), or a carbonate bond (—O—C(═O)—O—); and combinations of the above-described non-hydrocarbon oxygen atom-containing linking groups with an alkylene group. Further, a sulfonyl group (—SO₂—) may be further linked to the combination. Examples of such a divalent linking group having an oxygen atom include linking groups respectively represented by Formulae (y-a1-1) to (y-a1-7).

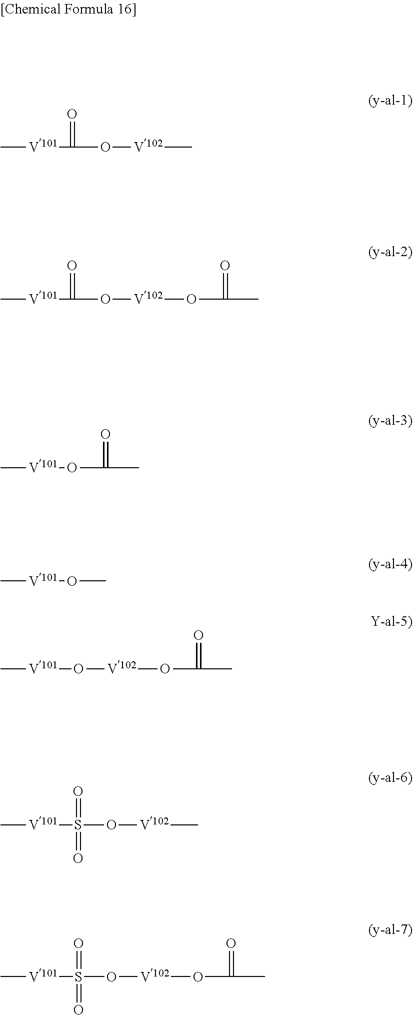

[In the formulae, V′¹⁰¹ represents a single bond or an alkylene group having 1 to carbon atoms, and V′¹⁰² represents a divalent saturated hydrocarbon group having 1 to 30 carbon atoms.]

The divalent saturated hydrocarbon group as V′¹⁰² is preferably an alkylene group having 1 to 30 carbon atoms, more preferably an alkylene group having 1 to 10 carbon atoms, and still more preferably an alkylene group having 1 to 5 carbon atoms.

The alkylene group as V′¹⁰¹ and V′¹⁰² may be a linear alkylene group or a branched alkylene group, and a linear alkylene group is preferable.

Specific examples of the alkylene group as V′¹⁰¹ and V′¹⁰² include a methylene group [—CH₂—]; an alkylmethylene group such as —CH(CH₃)—, —CH(CH₂CH₃)—, —C(CH₃)₂—, —C(CH₃)(CH₂CH₃)—, —C(CH₃)(CH₂CH₂CH₃)—, or —C(CH₂CH₃)₂—; an ethylene group [—CH₂CH₂—]; an alkylethylene group such as —CH(CH₃)CH₂—, —CH(CH₃)CH(CH₃)—, —C(CH₃)₂CH₂—, or —CH(CH₂CH₃)CH₂—; a trimethylene group (n-propylene group) [—CH₂CH₂CH₂—]; an alkyltrimethylene group such as —CH(CH₃)CH₂CH₂— or —CH₂CH(CH₃)CH₂—; a tetramethylene group [—CH₂CH₂CH₂CH₂—]; an alkyltetramethylene group such as —CH(CH₃)CH₂CH₂CH₂— or —CH₂CH(CH₃)CH₂CH₂—; and a pentamethylene group [—CH₂CH₂CH₂CH₂CH₂—].

Further, a part of the methylene group in the alkylene group as V′¹⁰¹ and V′¹⁰² may be substituted with a divalent aliphatic cyclic group having 5 to 10 carbon atoms. As the aliphatic cyclic group, a cyclohexylene group, a 1,5-adamantylene group, or a 2,6-adamantylene group is preferable.

Y¹⁰¹ represents preferably a divalent linking group having an ester bond or a divalent linking group having an ether bond, more preferably a linking group represented by any of Formulae (y-a1-1) to (y-a1-5), and still more preferably a linking group represented by any of Formulae (y-a1-1) to (y-a1-3).

In Formula (b-1), V¹⁰ represents a single bond, an alkylene group, or a fluorinated alkylene group. It is preferable that the alkylene group and the fluorinated alkylene group as V¹⁰¹ have 1 to 4 carbon atoms. Examples of the fluorinated alkylene group as V¹⁰¹ include a group in which some or all hydrogen atoms in the alkylene group as V¹⁰¹ have been substituted with fluorine atoms. Among these examples, it is preferable that V¹⁰¹ represents a single bond or a fluorinated alkylene group having 1 to 4 carbon atoms.

In Formula (b-1), R¹⁰² represents a fluorine atom or a fluorinated alkyl group having 1 to 5 carbon atoms. R¹⁰² represents preferably a fluorine atom or a perfluoroalkyl group having 1 to 5 carbon atoms and more preferably a fluorine atom.

In a case where Y¹⁰¹ represents a single bond, specific example of the anion moiety of the component (b-1) include a fluorinated alkylsulfonate anion such as a trifluoromethanesulfonate anion or a perfluorobutanesulfonate anion. Further, in a case where Y¹⁰¹ represents a divalent linking group having an oxygen atom, specific examples thereof include an anion represented by any of Formulae (an-1) to (an-3).

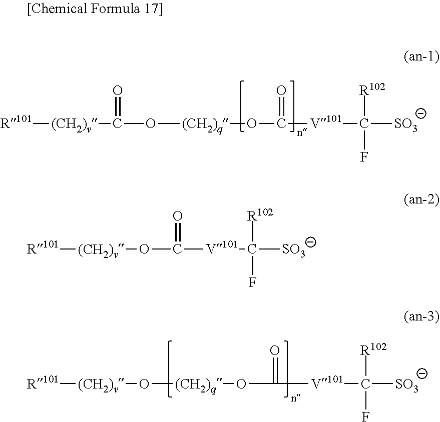

[In the formulae, R″¹⁰¹ represents an aliphatic cyclic group which may have a substituent, a group represented by any of Formulae (r-hr-1) to (r-hr-6), or a chain-like alkyl group which may have a substituent, R″¹⁰² represents an aliphatic cyclic group which may have a substituent, R″¹⁰³ represents an aromatic cyclic group which may have a substituent, an aliphatic cyclic group which may have a substituent, or a chain-like alkenyl group which may have a substituent, each v″ independently represents an integer of 0 to 3, each q″ independently represents an integer of 1 to 20, t″ represents an integer of 1 to 3, and n″ represents 0 or 1.]

As the aliphatic cyclic group which may have a substituent as R″¹⁰¹, R″¹⁰², and R″¹⁰³, the same groups as those for the cyclic aliphatic hydrocarbon group as R¹⁰¹ are preferable. Examples of the substituent include the same groups as those for the substituent which may substitute the cyclic aliphatic hydrocarbon group as R¹⁰².

As the aromatic cyclic group which may have a substituent as R″¹⁰³, the same groups as those for the aromatic hydrocarbon group in the cyclic hydrocarbon group as R¹⁰¹ are preferable. Examples of the substituent include the same groups as those for the substituent which may substitute the aromatic hydrocarbon group as R¹⁰¹.

As the chain-like alkyl group which may have a substituent as R″¹⁰¹, the same groups as those for the chain-like alkyl group as R¹⁰¹ are preferable. As the chain-like alkenyl group which may have a substituent as R″¹⁰³, the same groups as those for the chain-like alkenyl group as R¹⁰¹ are preferable.

In the present invention, an anion represented by Formula (an-1) is preferable. In Formula (an-1), it is preferable that v″ represents 0, q″ represents 2, t″ represents 1, n″ represents 1, and R″¹⁰¹ represents a cyclic hydrocarbon group which may have a substituent. Further, in Formula (an-2), it is preferable that v″ represents 0, t″ represents 1, and R″¹⁰² represents a cyclic hydrocarbon group which may have a substituent.

Anion Moiety of Component (b-2)

In Formula (b-2), R¹⁰⁴ and R¹⁰⁵ each independently represent a halogen atom, a cyclic group which may have a substituent, a chain-like alkyl group which may have a substituent, or a chain-like alkenyl group which may have a substituent, and examples thereof include the same groups as those for R¹⁰¹ in Formula (b-1). Here, R¹⁰⁴ and R¹⁰⁵ may be bonded to each other to form a ring.

R¹⁰⁴ and R¹⁰⁵ represent preferably a chain-like alkyl group which may have a substituent and more preferably a linear or branched alkyl group or a linear or branched fluorinated alkyl group.

Further, the number of carbon atoms of the chain-like alkyl group is preferably in a range of 1 to 10, more preferably in a range of 1 to 7, and still more preferably in a range of 1 to 3. It is preferable that the number of carbon atoms in the chain-like alkyl group as R¹⁰⁴ and R¹⁰⁵ decreases within the range of the number of carbon atoms from the viewpoint that the solubility in a solvent for a resist is also satisfactory. Further, in the chain-like alkyl group as R¹⁰⁴ and R¹⁰⁵, it is preferable that the number of hydrogen atoms substituted with fluorine atoms is as large as possible from the viewpoint that the acid strength increases and the transparency to high energy light or electron beams having a wavelength of 200 nm or less is improved.

The proportion of fluorine atoms in the chain-like alkyl group, that is, the fluorination ratio is preferably in a range of 70% to 100% and more preferably in a range of 90% to 100%, and it is most preferable that the chain-like alkyl group is a perfluoroalkyl group in which all hydrogen atoms are substituted with fluorine atoms.

In Formula (b-2), V¹⁰² and V¹⁰³ each independently represent a single bond, an alkylene group, or a fluorinated alkylene group, and examples thereof include the same groups as those for V¹⁰¹ in Formula (b-1).

In Formula (b-2), L¹⁰¹ and L¹⁰² each independently represent a single bond or an oxygen atom.

Anion Moiety of Component (b-3)

In Formula (b-3), R¹⁰⁶ to R¹⁰⁸ each independently represent a halogen atom, a cyclic group which may have a substituent, a chain-like alkyl group which may have a substituent, or a chain-like alkenyl group which may have a substituent, and examples thereof include the same groups as those for R¹⁰¹ in Formula (b-1).

L¹⁰³ to L¹⁰⁵ each independently represent a single bond, —CO—, or —SO₂—.

{Cation Moiety}

Cation Moiety of Component (b-1)

In Formulae (b-1), (b-2), and (b-3), m represents an integer of 1 or greater, M′^{m+} represents an m-valent onium cation, and suitable examples thereof include a sulfonium cation and an iodonium cation. Further, an organic cation represented by any of Formulae (ca-1) to (ca-4) is particularly preferable.

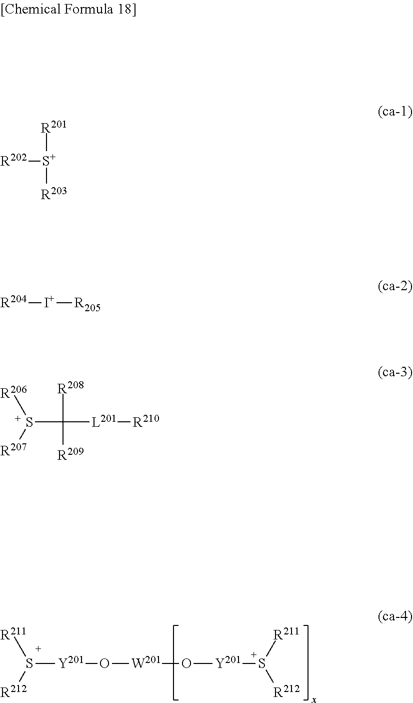

[In the formulae, R²⁰¹ to R²⁰⁷, R²¹¹, and R²¹² each independently represent an aryl group, an alkyl group, or an alkenyl group which may have a substituent, and R²⁰¹ to R²⁰³, R²⁰⁶ and R²⁰⁷, and R²¹¹ and R²¹² may be bonded to each other to form a ring with the sulfur atom in the formulae. R²⁰⁸ and R²⁰⁹ each independently represent a hydrogen atom or an alkyl group having 1 to 5 carbon atoms, R²¹⁰ represents an aryl group which may have a substituent, an alkyl group which may have a substituent, an alkenyl group which may have a substituent, or a —SO₂-containing cyclic group which may have a substituent, L²⁰¹ represents —C(═O)— or —C(═O)—O—, Y²⁰¹'s each independently represent an arylene group, an alkylene group, or an alkenylene group, x represents 1 or 2, and W²⁰¹ represents an (x+1)-valent linking group.]

Examples of the aryl group as R²⁰¹ to R²⁰⁷, R²¹¹, and R²¹² include an unsubstituted aryl group having 6 to 20 carbon atoms. Among the examples, a phenyl group or a naphthyl group is preferable.

As the alkyl group as R²⁰¹ to R²⁰⁷, R²¹¹, and R²¹², a chain-like or cyclic alkyl group having 1 to 30 carbon atoms is preferable.

As the alkenyl group represented by R²⁰¹ to R²⁰⁷, R²¹¹, and R²¹², an alkenyl group having 2 to 10 carbon atoms is preferable.

Examples of the substituent which may be included in R²⁰¹ to R²⁰⁷, R²¹¹, and R²¹² include an alkyl group, a halogen atom, a halogenated alkyl group, a carbonyl group, a cyano group, an amino group, an aryl group, and a group represented by any of Formulae (ca-r-1) to (ca-r-7).

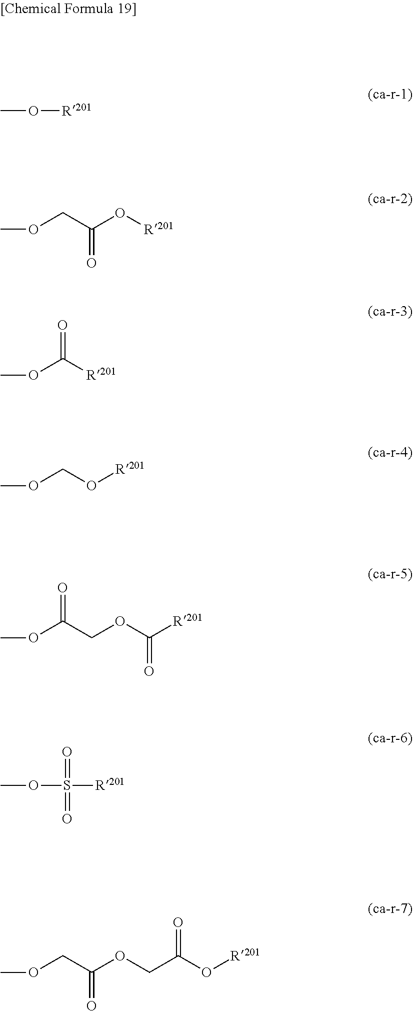

[In the formulae, each R′²⁰¹ independently represents a hydrogen atom, a cyclic group which may have a substituent, a chain-like alkyl group which may have a substituent, or a chain-like alkenyl group which may have a substituent.]

Examples of the cyclic group which may have a substituent, a chain-like alkyl group which may have a substituent, or a chain-like alkenyl group which may have a substituent as R′²⁰¹ include the same groups as those for R¹⁰¹ in Formula (b-1).

In a case where R²⁰¹ to R²⁰³, R²⁰⁶ and R²⁰⁷, and R²¹¹ and R²¹² are bonded to each other to form a ring with the sulfur atom in the formulae, these groups may be bonded to each other through a hetero atom such as a sulfur atom, an oxygen atom, or a nitrogen atom, or a functional group such as a carbonyl group, —SO—, —SO₂—, —SO₃—, —COO—, —CONH— or —N(R_{N})— (here, R_{N} represents an alkyl group having 1 to 5 carbon atoms). As a ring to be formed, one ring having a sulfur atom in the formulae in the ring skeleton thereof is preferably a 3- to 10-membered ring and particularly preferably a 5- to 7-membered ring including the sulfur atom. Specific examples of the ring to be formed include a thiophene ring, a thiazole ring, a benzothiophene ring, a thianthrene ring, a dibenzothiophene ring, a 9H-thioxanthene ring, a thioxanthone ring, a thianthrene ring, a phenoxathiin ring, a tetrahydrothiophenium ring, and a tetrahydrothiopyranium ring.

R²⁰⁸ and R²⁰⁹ each independently represent a hydrogen atom or an alkyl group having 1 to 5 carbon atoms and preferably a hydrogen atom or an alkyl group having 1 to 3 carbon atoms. In a case where R²⁰⁸ and R²⁰⁹ represent an alkyl group, R^{20′} and R²⁰⁹ may be bonded to each other to form a ring.

R²¹⁰ represents an aryl group which may have a substituent, an alkyl group which may have a substituent, an alkenyl group which may have a substituent, or a —SO₂-containing cyclic group which may have a substituent.

Examples of the aryl group as R²¹⁰ include an unsubstituted aryl group having 6 to 20 carbon atoms. Among these, a phenyl group or a naphthyl group is preferable.

As the alkyl group as R²¹⁰, a chain-like or cyclic alkyl group having 1 to 30 carbon atoms is preferable.

It is preferable that the alkenyl group as R²¹⁰ has 2 to 10 carbon atoms.

Y²⁰¹'s each independently represent an arylene group, an alkylene group, or an alkenylene group.

Examples of the arylene group as Y²⁰¹ include a group in which one hydrogen atom has been removed from the aryl group, which is an exemplary example as the aromatic hydrocarbon group represented by R¹⁰¹ in Formula (b-1).

Examples of the alkylene group and alkenylene group as Y²⁰¹ include a group in which one hydrogen atom has been removed from the chain-like alkyl group or the chain-like alkenyl group as R¹⁰¹ in Formula (b-1).

In Formula (ca-4), x represents 1 or 2.

W²⁰¹ represents an (x+1)-valent linking group, that is, a divalent or trivalent linking group.

As the divalent linking group represented by W²⁰¹, a divalent hydrocarbon group which may have a substituent is preferable. The divalent linking group as W²⁰¹ may be linear, branched, or cyclic and cyclic is more preferable. Among these, a group in which two carbonyl groups are combined with both ends of the arylene group is preferable. Examples of the arylene group include a phenylene group and a naphthylene group. Among these, a phenylene group is particularly preferable.

Examples of the trivalent linking group as W²⁰¹ include a group in which one hydrogen atom has been removed from a divalent linking group as W²⁰¹ and a group in which the divalent linking group is further bonded to the divalent linking group. As the trivalent linking group as W²⁰¹, a group in which two carbonyl groups are bonded to an arylene group is preferable.

Specific examples of suitable cations represented by Formula (ca-1) include cations respectively represented by Formulae (ca-1-1) to (ca-1-67).

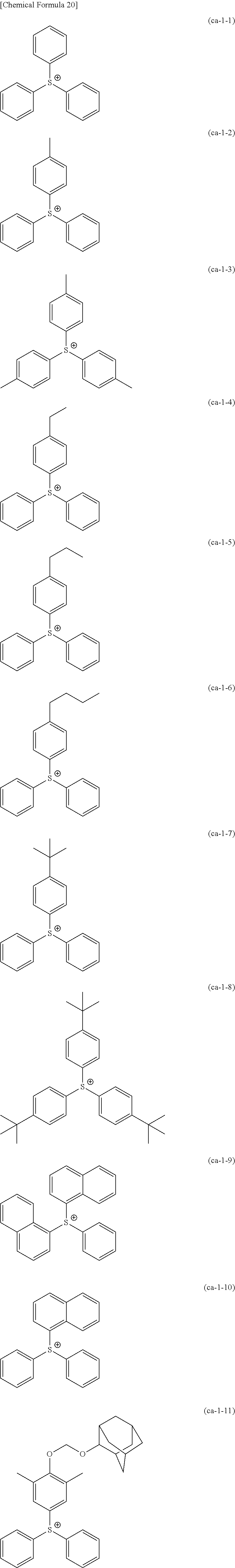

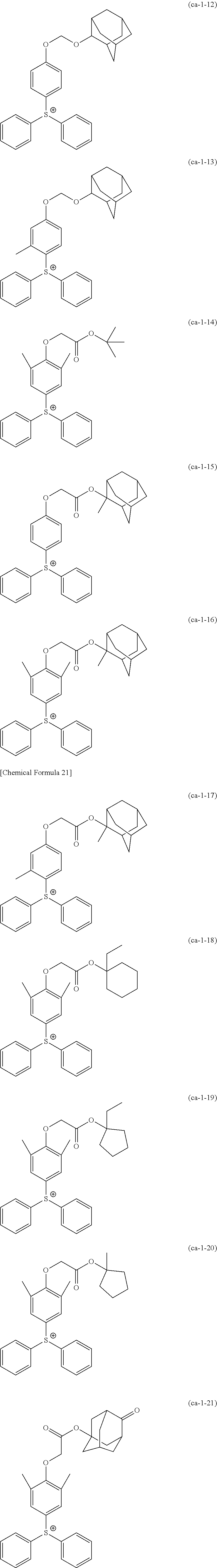

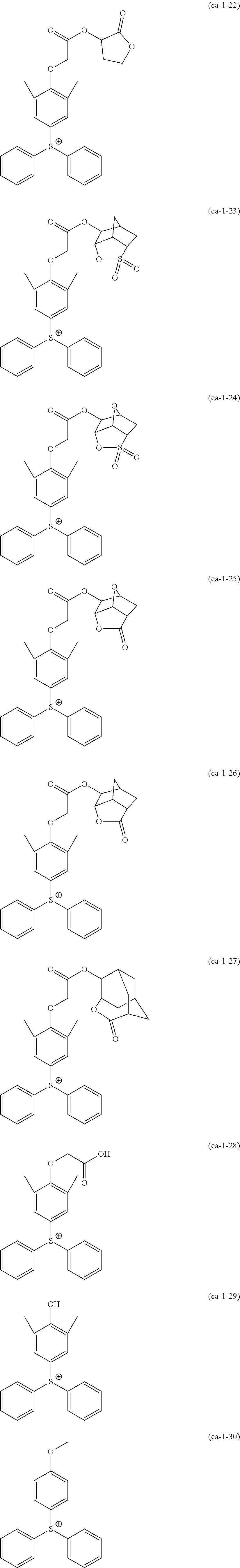

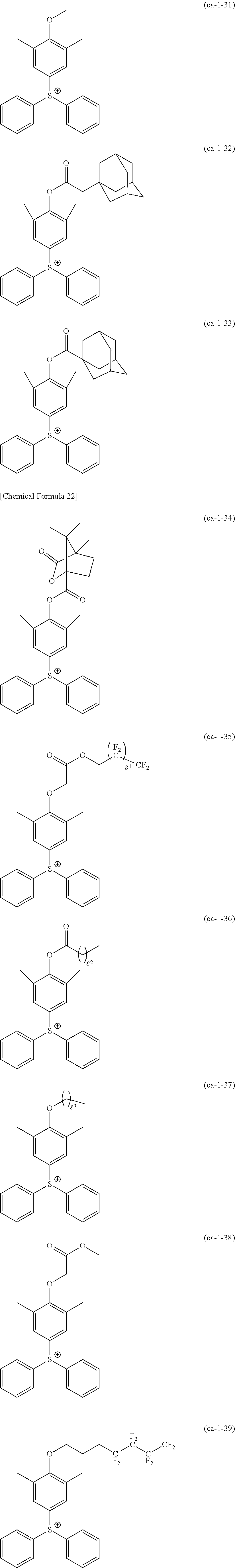

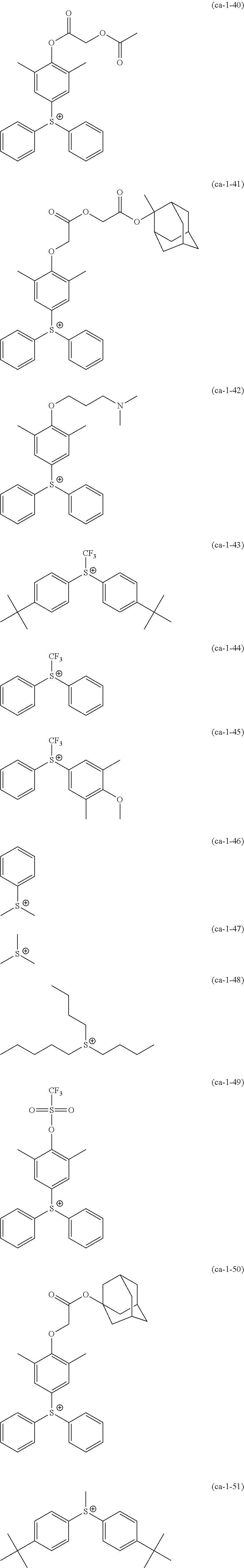

[In the formulae, g1, g2, and g3 represent a repeating number, g1 represents an integer of 1 to 5, g2 represents an integer of 0 to 20, and g3 represents an integer of 0 to 20.]

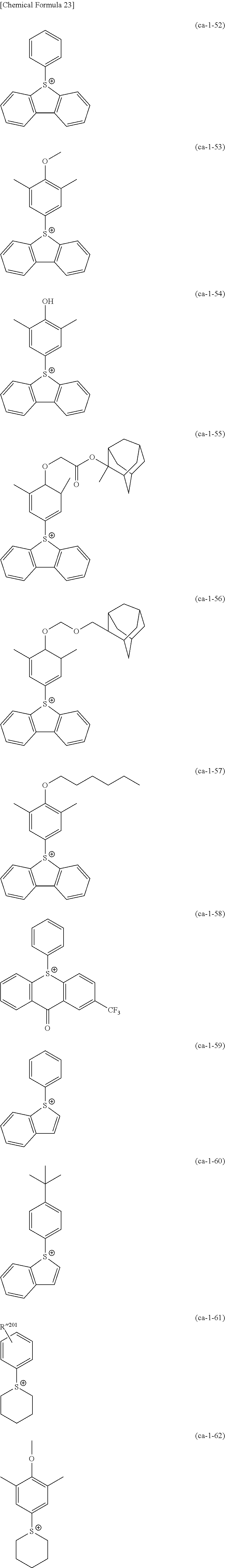

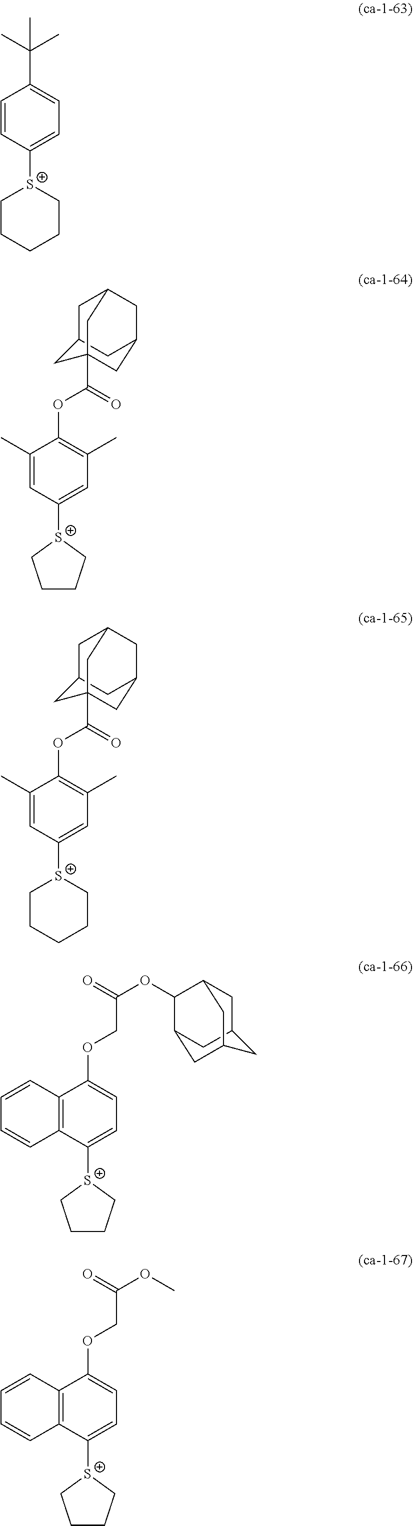 [SMILES: CC(C)(C)c1ccc([S+]2CCCCC2)cc1 ; Cc1cc([S+]2CCCC2)cc(C)c1OC(=O)C12CC3CC(CC(C3)C1)C2 ; Cc1cc([S+]2CCCCC2)cc(C)c1OC(=O)C12CC3CC(CC(C3)C1)C2 ; O=C(COc1ccc([S+]2CCCC2)c2ccccc12)OC1C2CC3CC(C2)CC1C3 ; COC(=O)COc1ccc([S+]2CCCC2)c2ccccc12]

[In the formulae, R″²⁰¹ represents a hydrogen atom or a substituent, and examples of the substituent include the same groups as those for the substituents which may be included in R²⁰¹ to R²⁰⁷ and R²¹⁰ to R²¹².]

Specific examples of suitable cations represented by Formula (ca-2) include a diphenyliodonium cation and a bis(4-tert-butylphenyl)iodonium cation.

Specific examples of suitable cations represented by Formula (ca-3) include cations respectively represented by Formulae (ca-3-1) to (ca-3-6).

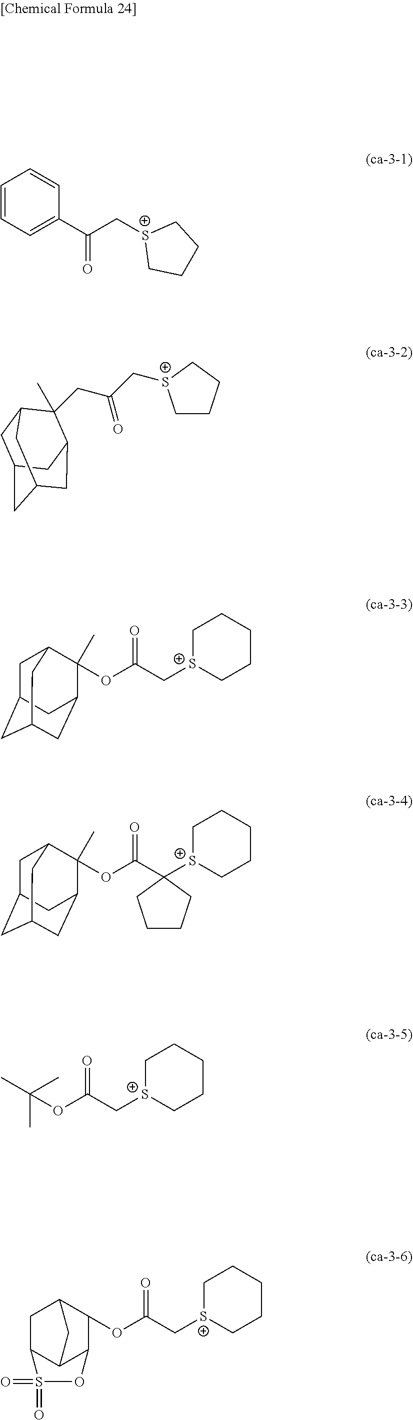

Specific examples of suitable cations represented by Formula (ca-4) include cations respectively represented by Formulae (ca-4-1) and (ca-4-2).

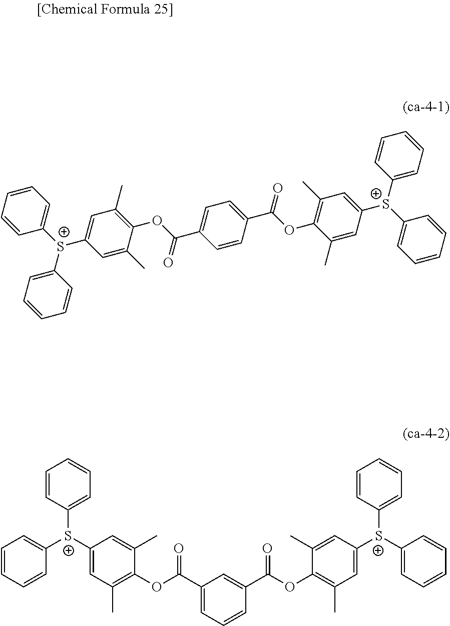 [SMILES: Cc1cc([S+](c2ccccc2)c2ccccc2)cc(C)c1OC(=O)c1ccc(C(=O)Oc2c(C)cc([S+](c3ccccc3)c3ccccc3)cc2C)cc1 ; Cc1cc([S+](c2ccccc2)c2ccccc2)cc(C)c1OC(=O)c1cccc(C(=O)Oc2c(C)cc([S+](c3ccccc3)c3ccccc3)cc2C)c1]

Among the examples, as the cation moiety [(M′^{m+})_{l/m}], a cation represented by Formula (ca-1) is preferable, a cation represented by any of Formulae (ca-1-1) to (ca-1-67) is more preferable, a cation represented by any of Formulae (ca-1-1), (ca-1-2), and (ca-1-16) is still more preferable, and a cation represented by any of Formulae (ca-1-2) and (ca-1-16) is particularly preferable.

As a preferred example of the component (B), a combination of a trifluoromethanesulfonate anion moiety, an anion moiety in which in Formula (an-1), v″ represents 0, q″ represents 2, t″ represents 1, n″ represents 1, and R″¹⁰¹ represents a cyclic hydrocarbon group which may have a substituent, or an anion moiety in which in Formula (an-2), v″ represents 0, t″ represents 1, and R″¹⁰² represents a cyclic hydrocarbon group which may have a substituent and a cation represented by any of Formulae (ca-1-1), (ca-1-2), and (ca-1-16) is preferable.

Among these, a combination of an anion moiety in which in Formula (an-1), v″ represents 0, q″ represents 2, t″ represents 1, n″ represents 1, and R″¹⁰¹ represents a cyclic hydrocarbon group which may have a substituent or an anion moiety in which in Formula (an-2), v″ represents 0, t″ represents 1, and R″¹⁰² represents a cyclic hydrocarbon group which may have a substituent and a cation represented by any of Formulae (ca-1-2) and (ca-1-16) is more preferable.

As the component (B), these acid generators may be used alone or in combination of two or more kinds thereof.

From the viewpoint of forming a thick-film resist pattern having a satisfactory shape, the content of the component (B) in the resist composition for forming a thick-film resist film of the present invention is preferably in a range of 0.1 to 10 parts by mass, more preferably in a range of 0.1 to 5 parts by mass, and still more preferably in a range of 0.3 to 3 parts by mass with respect to 100 parts by mass of the component (A). In a case where the content thereof is in the above-described range, a uniform solution can be obtained and the storage stability is improved.

<Acid Diffusion Control Agent Component (D)>

The resist composition for forming a thick-film resist film of the present invention may further contain an acid diffusion control agent (D) (hereinafter, also referred to as a “component (D)”) in addition to the component (A) and the acid generator component (B). The component (D) is not particularly limited, and an optional one can be appropriately selected from those which have been known as an acid diffusion control agent in a resist composition in the related art and then used. The component (D) functions as a quencher (an acid diffusion control agent) which traps an acid generated upon light exposure in the resist composition.

The component (D) may be a photodecomposable base (D1) (hereinafter, referred to as a “component (D1)”) which is decomposed upon light exposure and loses an acid diffusion controllability or a nitrogen-containing organic compound (D2) (hereinafter, referred to as a component (D2)″) that does not correspond to the component (D1).

In Regard to Component (D1)

In a case where a resist composition containing the component (D1) is employed, the contrast between an exposed portion and an unexposed portion can be further improved in a case of forming a photoresist pattern.

The component (D1) is not particularly limited as long as the component is decomposed upon light exposure and loses the acid diffusion controllability, and one or more compounds selected from the group consisting of a compound represented by Formula (d1-1) (hereinafter, referred to as a “component (d1-1)”), a compound represented by Formula (d1-2) (hereinafter, referred to as a “component (d1-2)”), and a compound represented by Formula (d1-3) (hereinafter, referred to as a “component (d1-3)”) are preferable.

Since the components (d1-1) to (d1-3) are decomposed and lose the acid diffusion controllability (basicity), the components (d1-1) to (d1-3) do not function as a quencher at the exposed portion of the photoresist film, but function as a quencher at the unexposed portion thereof.

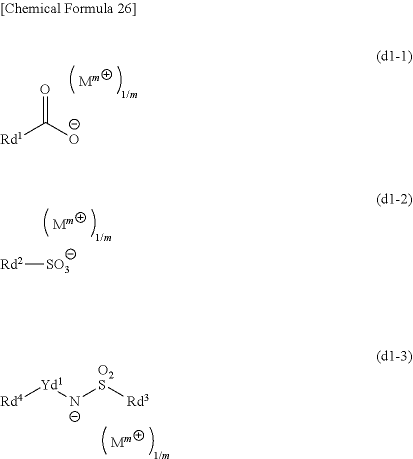

[In the formulae, Rd¹ to Rd⁴ represent a cyclic group which may have a substituent, a chain-like alkyl group which may have a substituent, or a chain-like alkenyl group which may have a substituent. Here, the carbon atom adjacent to the S atom as Rd² in Formula (d1-2) has no fluorine atom bonded thereto. Yd¹ represents a single bond or a divalent linking group. m represents an integer of 1 or greater, and each M^{m+} independently represents an m-valent organic cation.]

{Component (d1-1)}

Anion Moiety

In Formula (d1-1), Rd¹ represents a cyclic group which may have a substituent, a chain-like alkyl group which may have a substituent, or a chain-like alkenyl group which may have a substituent.

Among these, it is preferable that the group as Rd¹ represents an aromatic hydrocarbon group which may have a substituent, an aliphatic cyclic group which may have a substituent, and a chain-like alkyl group which may have a substituent. Examples of the substituent that may be included in these groups include a hydroxyl group, an oxo group, an alkyl group, an aryl group, a fluorine atom, a fluorinated alkyl group, an ether bond, an ester bond, and a combination thereof. In a case where an ether bond or an ester bond is included as the substituent, an alkylene group may be interposed.

As the aromatic hydrocarbon group, a phenyl group or a naphthyl group is more preferable.

As the aliphatic cyclic group, a group in which one or more hydrogen atoms have been removed from a polycycloalkane such as adamantane, norbornane, isobornane, tricyclodecane or tetracyclododecane is more preferable.

It is preferable that the chain-like alkyl group has 1 to 10 carbon atoms, and specific examples thereof include a linear alkyl group such as a methyl group, an ethyl group, a propyl group, a butyl group, a pentyl group, a hexyl group, a heptyl group, an octyl group, a nonyl group, or a decyl group; and a branched alkyl group such as a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, or a 4-methylpentyl group.

In a case where the chain-like alkyl group may have a fluorine atom or a fluorinated alkyl group as a substituent, the fluorinated alkyl group has preferably 1 to 11 carbon atoms, more preferably 1 to 8 carbon atoms, and still more preferably 1 to 4 carbon atoms. The fluorinated alkyl group may have an atom other than a fluorine atom. Examples of the atom other than the fluorine atom include an oxygen atom, a sulfur atom, and a nitrogen atom.

Rd¹ represents preferably a fluorinated alkyl group in which some or all hydrogen atoms constituting a linear alkyl group have been substituted with fluorine atoms and particularly preferably a fluorinated alkyl group in which all hydrogen atoms constituting a linear alkyl group have been substituted with fluorine atoms (a linear perfluoroalkyl group).

Specific preferred examples of the anion moiety in the component (d1-1) are described below.

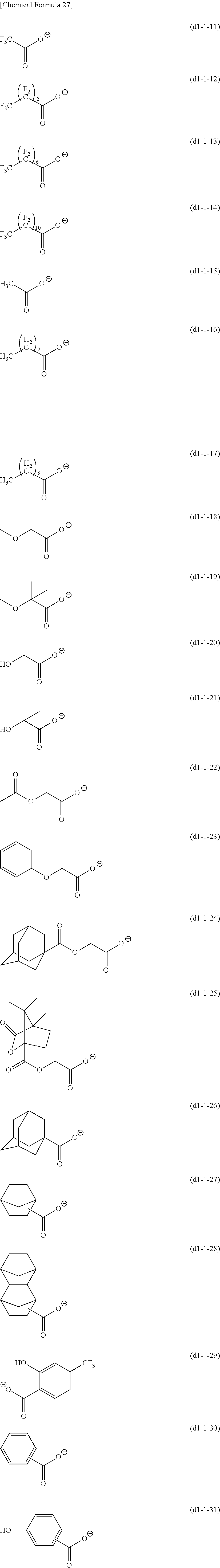

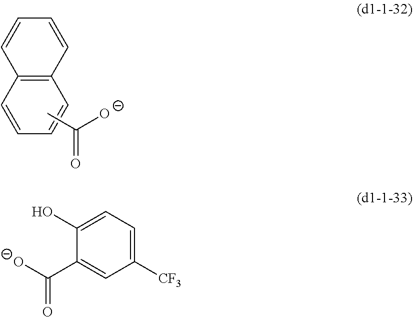

Cation Moiety

In Formula (d1-1), M^{m+} represents an m-valent organic cation.

Suitable examples of the organic cation as M^{m+} include those for the cations respectively represented by Formulae (ca-1) to (ca-4). Among these, the cation represented by Formula (ca-1) is more preferable, and the cations respectively represented by Formulae (ca-1-1) to (ca-1-67) are still more preferable.

The component (d1-1) may be used alone or in combination of two or more kinds thereof.

{Component (d1-2)}

Anion Moiety

In Formula (d1-2), Rd² represents a cyclic group which may have a substituent, a chain-like alkyl group which may have a substituent, or a chain-like alkenyl group which may have a substituent.

Here, the carbon atom adjacent to the S atom in Rd² has no fluorine atom bonded thereto (the carbon atom is not substituted with a fluorine atom). In this manner, the anion of the component (d1-2) becomes an appropriately weak acid anion, thereby improving the quenching ability of the component (D).

It is preferable that Rd² represents a chain-like alkyl group which may have a substituent or an aliphatic cyclic group which may have a substituent. The chain-like alkyl group has preferably 1 to 10 carbon atoms and more preferably 3 to 10 carbon atoms. As the aliphatic cyclic group, a group in which one or more hydrogen atoms have been removed from adamantane, norbornane, isobornane, tricyclodecane, or tetracyclododecane (a group which may have a substituent); and a group in which one or more hydrogen atoms have been removed from camphor are more preferable.

The hydrocarbon group as Rd² may have a substituent, and examples of the substituent include the same groups as those for the substituent which may be included in the hydrocarbon group (such as an aromatic hydrocarbon group, an aliphatic cyclic group, or a chain-like alkyl group) as Rd¹ in Formula (d1-1).

Specific preferred examples of the anion moiety in the component (d1-2) are described below.

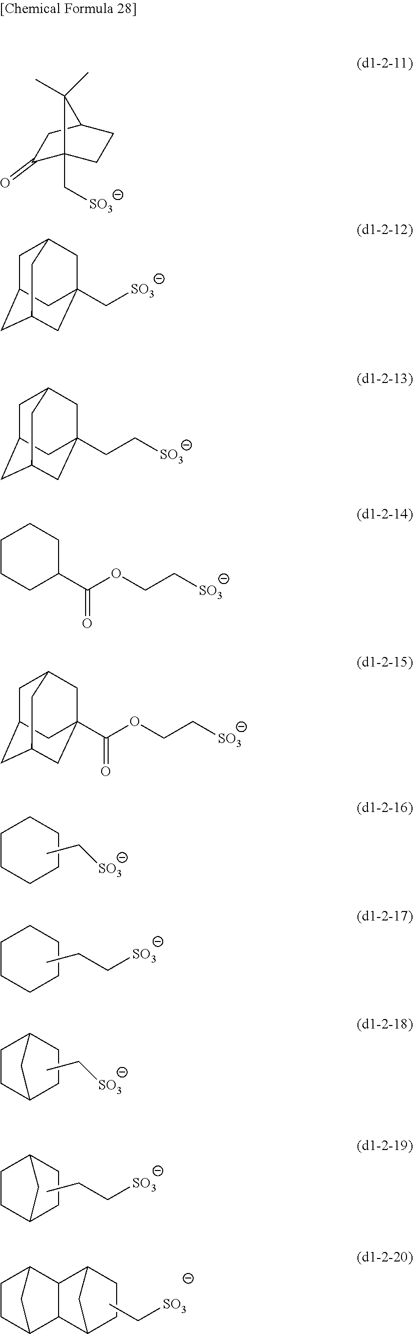

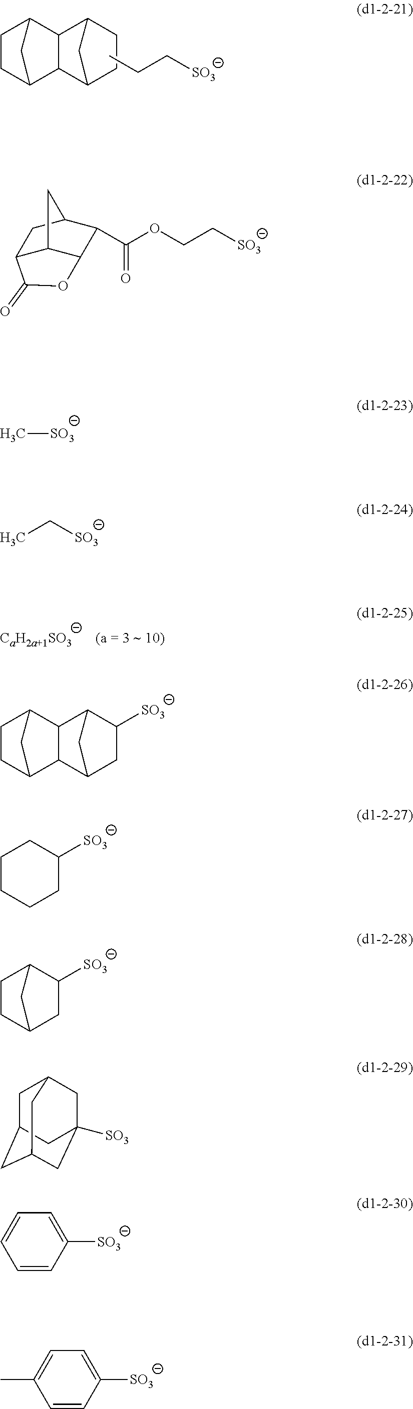

Cation Moiety

In Formula (d1-2), M^{m+} represents an m-valent organic cation and has the same definition as that for M^{m} in Formula (d1-1).

The component (d1-2) may be used alone or in combination of two or more kinds thereof.

{Component (d1-3)}

Anion Moiety

In Formula (d1-3), Rd³ represents a cyclic group which may have a substituent, a chain-like alkyl group which may have a substituent, or a chain-like alkenyl group which may have a substituent. Among these, a cyclic group having a fluorine atom, a chain-like alkyl group, or a chain-like alkenyl group is preferable. Among these, a fluorinated alkyl group is preferable, and the same groups as those for the fluorinated alkyl group represented by Rd¹ are more preferable.

In Formula (d1-3), Rd⁴ represents a cyclic group which may have a substituent, a chain-like alkyl group which may have a substituent, or a chain-like alkenyl group which may have a substituent.

Among these, an alkyl group which may have a substituent, an alkoxy group which may have a substituent, an alkenyl group which may have a substituent, or a cyclic group which may have a substituent is preferable.

It is preferable that the alkyl group as Rd⁴ is a linear or branched alkyl group having 1 to 5 carbon atoms, and specific examples thereof include a methyl group, an ethyl group, a propyl group, an isopropyl group, an n-butyl group, an isobutyl group, a tert-butyl group, a pentyl group, an isopentyl group, and a neopentyl group. Some hydrogen atoms in the alkyl group as Rd⁴ may be substituted with a hydroxyl group, a cyano group, or the like.

It is preferable that the alkoxy group as Rd⁴ is an alkoxy group having 1 to 5 carbon atoms, and specific examples of the alkoxy group having 1 to 5 carbon atoms include a methoxy group, an ethoxy group, an n-propoxy group, an iso-propoxy group, an n-butoxy group, and a tert-butoxy group. Among these, a methoxy group and an ethoxy group are preferable.

As the alkenyl group represented by Rd⁴, a vinyl group, a propenyl group (an allyl group), a 1-methylpropenyl group, and a 2-methylpropenyl group are preferable. These groups may have an alkyl group having 1 to 5 carbon atoms or a halogenated alkyl group having 1 to 5 carbon atoms as a substituent.

As the cyclic group represented by Rd⁴, an alicyclic group in which one or more hydrogen atoms have been removed from a cycloalkane such as cyclopentane, cyclohexane, adamantane, norbornane, isobornane, tricyclodecane, or tetracyclododecane or an aromatic group such as a phenyl group or a naphthyl group is preferable. In a case where Rd⁴ represents an alicyclic group, the photoresist composition is satisfactorily dissolved in a solvent, and thus the lithography characteristics are improved. Further, in a case where Rd⁴ represents an aromatic group, the photoresist composition has excellent light absorption efficiency in lithography using EUV or the like as an exposure light source, and thus the sensitivity and lithography characteristics are improved.

In Formula (d1-3), Yd¹ represents a single bond or a divalent linking group.

The divalent linking group as Yd¹ is not particularly limited, and examples thereof include a divalent hydrocarbon group (an aliphatic hydrocarbon group or an aromatic hydrocarbon group) which may have a substituent and a divalent linking group having a hetero atom.

It is preferable that Yd¹ represents a carbonyl group, an ester bond, an amide bond, an alkylene group, or a combination of these. As the alkylene group, a linear or branched alkylene group is more preferable, and a methylene group or an ethylene group is still more preferable.

Specific preferred examples of the anion moiety in the component (d1-3) are described below.

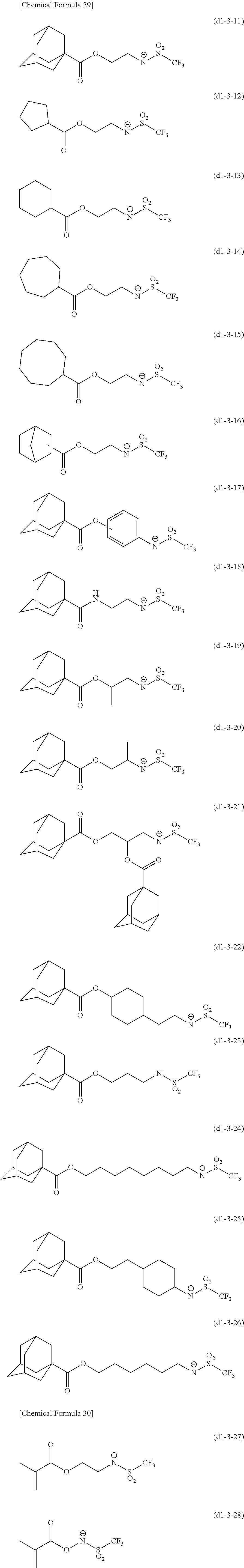

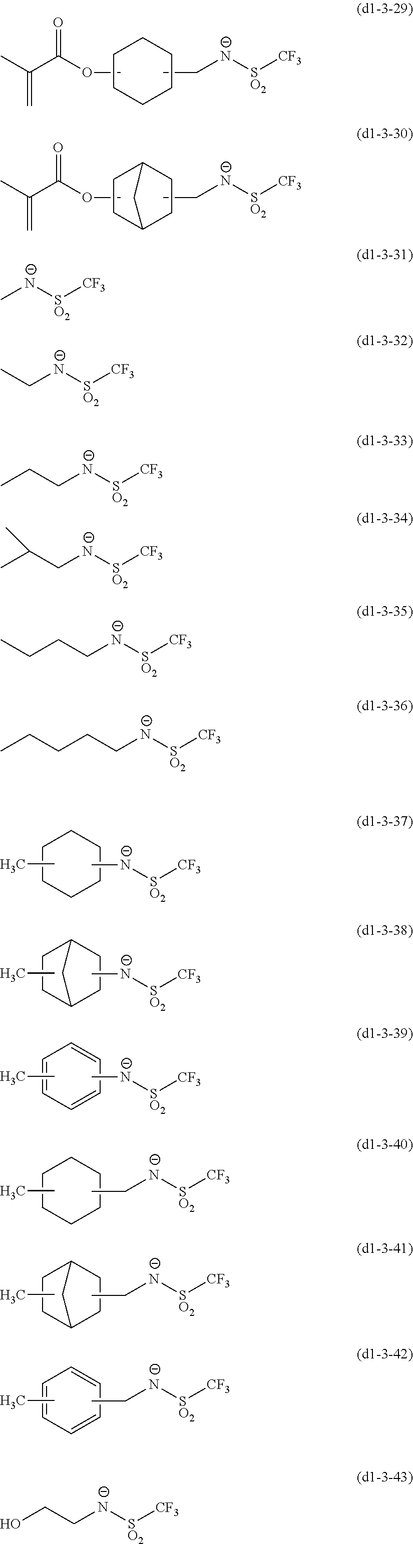

Cation Moiety

In Formula (d1-3), M^{m+} represents an m-valent organic cation and has the same definition as that for M^{m+} in Formula (d1-1).

The component (d1-3) may be used alone or in combination of two or more kinds thereof.

As the component (D1), only one of the above-described components (d1-1) to (d1-3) or a combination of two or more kinds thereof may be used.

Among the examples, it is preferable to use at least the component (d1-1) as the component (D1).

In a case where the resist composition contains the component (D1), the content of the component (D1) is preferably in a range of 0.3 to 5 parts by weight, more preferably in a range of 0.5 to 4 parts by weight, and still more preferably in a range of 0.7 to 3 parts by weight with respect to 100 parts by weight of the component (S).

In a case where the content of the component (D1) is greater than or equal to the lower limit of the above-described preferable range, particularly excellent lithography characteristics and an excellent photoresist pattern shape are easily obtained. On the contrary, in a case where the content is less than or equal to the upper limit of the above-described range, the sensitivity can be satisfactorily maintained and the throughput is also excellent.

Method of Producing Component (D1):

The methods of producing the component (d1-1) and the component (d1-2) are not particularly limited, and these components can be produced according to known methods.

Further, the method of producing the component (d1-3) is not particularly limited, and the component (d1-3) can be produced according to the same method as described in United States Patent Application, Publication No. 2012-0149916.

In Regard to Component (D2)

The resist composition may contain, as the acid diffusion control agent component, a nitrogen-containing organic compound component (hereinafter, referred to as a “component (D2)”) that does not correspond to the component (D1) described above.

The component (D2) is not particularly limited as long as the component functions as an acid diffusion control agent and does not correspond to the component (D1), and an optional component may be selected from known components and then used. Among these, an aliphatic amine and an aromatic amine are preferable.

The aliphatic amine is an amine containing one or more aliphatic groups, and the number of carbon atoms in the aliphatic group is preferably in a range of 1 to 12.

Examples of these aliphatic amine include amines in which at least one hydrogen atom of ammonia NH₃ has been substituted with an alkyl group or hydroxyalkyl group having 12 or less carbon atoms (alkyl amines or alkyl alcohol amines), and cyclic amines.

Specific examples of the alkyl amines and the alkyl alcohol amines include monoalkylamines such as n-hexylamine, n-heptylamine, n-octylamine, n-nonylamine, and n-decylamine; dialkylamines such as diethylamine, di-n-propylamine, di-n-heptylamine, di-n-octylamine, and dicyclohexylamine; trialkylamines such as trimethylamine, triethylamine, tri-n-propylamine, tri-n-butylamine, tri-n-pentylamine, tri-n-hexylamine, tri-n-heptylamine, tri-n-octylamine, tri-n-nonylamine, tri-n-decylamine, and tri-n-dodecylamine; and alkyl alcohol amines such as diethanolamine, triethanolamine, diisopropanolamine, triisopropanolamine, di-n-octanolamine, and tri-n-octanolamine. Among these, a trialkylamine having 5 to 10 carbon atoms is preferable, and tri-n-decylamine is particularly preferable.

Examples of the cyclic amine include a heterocyclic compound having a nitrogen atom as a hetero atom. The heterocyclic compound may be a monocyclic compound (aliphatic monocyclic amine) or a polycyclic compound (aliphatic polycyclic amine).

Specific examples of the aliphatic monocyclic amine include piperidine and piperazine.

The aliphatic polycyclic amine preferably has 6 to 10 carbon atoms, and specific examples thereof include 1, 5-diazabicyclo[4.3.0]-5-nonene, 1,8-diazabicyclo[5.4.0]-7-undecene, hexamethylenetetramine, and 1,4-diazabicyclo[2.2.2]octane.

Examples of other aliphatic amines include tris(2-methoxymethoxyethyl)amine, tris{2-(2-methoxyethoxy)ethyl}amine, tris{2-(2-methoxyethoxymethoxy)ethyl}amine, tris{2-(1-methoxyethoxy)ethyl}amine, tris{2-(1-ethoxyethoxy)ethyl}amine, tris{2-(1-ethoxypropoxy)ethyl}amine, tris[2-{2-(2-hydroxyethoxy)ethoxy}ethyl]amine, and triethanolamine triacetate. Among these, triethanolamine triacetate is preferable.

As the component (D2), an aromatic amine may be used.

Examples of the aromatic amine include 4-dimethylaminopyridine, pyrrole, indole, pyrazole, imidazole, or derivatives thereof, tribenzylamine, 2,6-diisopropylaniline, N-tert-butoxycarbonylpyrrolidine, and 2,4-diamino-6-phenyl-1,3,5-triazine. Among these, N-tert-butoxycarbonylpyrrolidine and 2,4-diamino-6-phenyl-1,3,5-triazine are preferable, and 2,4-diamino-6-phenyl-1,3,5-triazine is more preferable.

The component (D2) may be used alone or in combination of two or more kinds thereof.

From the viewpoint of the effects of the present invention, the proportion of the component (D2) in the component (D) is preferably in a range of 10% to 100% by mass, more preferably in a range of 50% to 100% by mass, and still more preferably 100% by mass.

From the viewpoint of obtaining an excellent resist pattern, as the component (D) of the present invention, the component (D2) is preferable, and among these, an aliphatic amine (alkylamine or alkyl alcohol amine) is more preferable, an alkylamine chain-like tertiary aliphatic amine is still more preferable, and tri-n-decylamine is particularly preferable.

The reason why such an effect is obtained is not clear, but it is assumed that a tertiary aliphatic amine is uniformly dispersed in a resist film so that the diffusion of an acid generated from the component (B) can be effectively suppressed. Further, in a case where the resist composition contains the component (D) such as a tertiary aliphatic amine, the temporal stability (post exposure stability of the latent image formed by the pattern-wise exposure of the resist layer) after the light exposure of the resist composition is also improved.

In the resist composition for forming a thick-film resist film of the present invention, the content of the component (D) is typically in a range of 0.005 to 5.0 parts by mass, preferably in a range of 0.005 to 0.3 parts by mass from the viewpoint of forming a thick-film resist pattern having a satisfactory shape, and more preferably in a range of 0.005 to 0.2 parts by mass with respect to 100 parts by mass of the component (A).

<Vinyl Group-Containing Compound Component (E)>

The resist composition for forming a thick-film resist film of the present invention further contains a vinyl group-containing compound component (E) (hereinafter, also referred to as a component (E)) in addition to the component (A), the component (B) and the component (D).

The vinyl group-containing compound is a compound containing two or more vinyl ether groups in which an oxygen atom of a vinyloxy group (CH₂═CH—O—) is bonded to a carbon atom. In a case where the resist composition contains such a compound, a thick-film resist pattern having excellent crack resistance and a satisfactory shape can be formed.

It is assumed that the vinyl group-containing compound exhibits the effect by functioning as a crosslinking agent with respect to the component (A). That is, it is assumed that in a case where the vinyl group-containing compound is heated during prebake, the crosslinking reaction with the component (A) is promoted, the mass average molecular weight of the component (A) increases, a soft film can be formed, and thus the effect of crack resistance is exhibited. Further, the dissolution contrast is assumed to be improved because after an alkali-insoluble resist layer is formed on the entire surface of a substrate, the crosslinking is decomposed due an action of an acid generated from the component (B) upon light exposure, the exposed portion is changed to be alkali-soluble, and the unexposed portion remains alkali-insoluble.

Specifically, as the vinyl group-containing compound, a plurality of compounds are described in Japanese Unexamined Patent Application, First Publication No. H06-148889, Japanese Unexamined Patent Application, First Publication No. H06-230574, and the like, and an optional compound can be selected from these compounds and then used. Particularly, from the viewpoint of the effects of the present invention, a compound etherified by substituting some or all hydrogen atoms of a hydroxyl group in alcohol represented by Formula (e-0) with a vinyl group is preferable.

[Chemical Formula 31]

Rb—(OH)_{b} (e-0)

In Formula (e-0), Rb represents a group in which b hydrogen atoms have been removed from an alkane of a linear group, a branched group, or a cyclic group and may have a substituent. Further, an oxygen bond (ether bond) may be present in the alkane.

b represents an integer of 2, 3, or 4.

Specific examples thereof include ethylene glycol divinyl ether, triethylene glycol divinyl ether, 1,3-butanediol divinyl ether, tetramethylene glycol divinyl ether, neopentyl glycol divinyl ether, trimethylpropane trivinyl ether, trimethylolethane trivinyl ether, hexanediol divinyl ether, 1,4-cyclohexanediol divinyl ether, tetraethylene glycol divinyl ether, pentaerythritol divinyl ether, pentaerythritol trivinyl ether, and cyclohexanedimethanol divinyl ether. Among these, a crosslinkable divinyl ether compound is more preferable.

It is preferable that the resist composition for forming a thick-film resist film of the present invention is represented by Formula (e-1) as the vinyl group-containing compound.

[Chemical Formula 32]

CH₂═CH—O—R²⁷—O—CH═CH₂ (e-1)

In Formula (e-1), R²⁷ represents a linear or branched alkylene group having 1 to 10 carbon atoms or a group represented by Formula (e-2).

R²⁷ may have a substituent and may also have an ether bond in the main chain.

Examples of the substituent in a case where R²⁷ may have a substituent include an alkyl group, an alkoxy group, a halogen atom, a halogenated alkyl group, a hydroxyl group, a carbonyl group, and a nitro group.

As the alkyl group as the substituent, an alkyl group having 1 to 5 carbon atoms is preferable, and a methyl group, an ethyl group, a propyl group, an n-butyl group, or a tert-butyl group is most preferable.

As the alkoxy group as the substituent, an alkoxy group having 1 to 5 carbon atoms is preferable, a methoxy group, an ethoxy group, an n-propoxy group, an iso-propoxy group, an n-butoxy group, or a tert-butoxy group is more preferable, and a methoxy group or an ethoxy group is still more preferable.

Examples of the halogen atom as the substituent include a fluorine atom, a chlorine atom, a bromine atom, and an iodine atom. Among these, a fluorine atom is preferable.

Example of the halogenated alkyl group as the substituent includes a group in which some or all hydrogen atoms in an alkyl group having 1 to 5 carbon atoms such as a methyl group, an ethyl group, a propyl group, an n-butyl group, or a tert-butyl group have been substituted with the halogen atoms.

The carbonyl group as the substituent is a group that substitutes a methylene group (—CH₂—) constituting the cyclic hydrocarbon group.

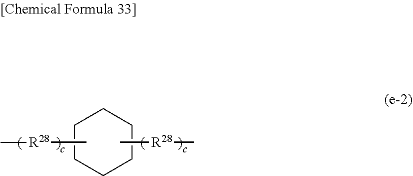

In Formula (e-2), R²⁸'s each independently represent a linear or branched alkylene group having 1 to 10 carbon atoms which may have a substituent, and the alkylene group may have an ether bond in the main chain.

Examples of the substituents which may be included in R²⁸ are the same as the substituents which may be included in R²⁷. c's each independently represent 0 or 1.

In Formula (e-1), R²⁷ represents preferably —C₄H₈—, —C₂H₄OC₂H₄—, —C₂H₄OC₂H₄OC₂H₄—, or a group represented by Formula (e-2), more preferably a group represented by Formula (e-2), and particularly preferably (cyclohexanemethanoldivinyl ether) in which R²⁸ in Formula (e-2) represents an alkylene group (methylene group) having one carbon atom and c represents 1.

The component (E) may be used alone or in combination of two or more kinds thereof.

From the viewpoint of the effect of the present invention, that is, the effect of the crack resistance, the content of the component (E) in the resist composition for forming a thick-film resist film of the present invention is preferably in a range of 1 to 15 parts by mass and more preferably in a range of 3 to 10 parts by mass with respect to 100 parts by mass of the component (A). In a case where the content thereof is set to be in the above-described range, a resist pattern having a satisfactory shape can be formed. Further, it is preferable that the content thereof is in the above-described range from the viewpoint that a uniform solution can be obtained and the storage stability is improved.

<Organic Solvent (S)>

The resist composition for forming a thick-film resist film of the present invention can be produced by dissolving the materials in an organic solvent (hereinafter, also referred to as a “component (S)”).

The component (S) may be any organic solvent which can dissolve the respective components to be used to obtain a uniform solution, and one or two or more optional organic solvents can be appropriately selected from those which have been known in the related art as solvents of a chemically amplified resist and then used. Examples thereof include lactones such as y-butyrolactone; ketones such as acetone, methyl ethyl ketone, cyclohexanone, methyl-n-amyl ketone, methyl isoamyl ketone, and 2-heptanone; polyhydric alcohols such as ethylene glycol, diethylene glycol, propylene glycol, and dipropylene glycol and derivatives thereof, compounds having an ester bond, such as ethylene glycol monoacetate, diethylene glycol monoacetate, propylene glycol monoacetate, and dipropylene glycol monoacetate; polyhydric alcohol derivatives of compounds having an ether bond such as monoalkyl ether or monophenyl ether, such as monomethyl ether, monoethyl ether, monopropyl ether, or monobutyl ether of polyhydric alcohols or compounds having an ester bond; cyclic ethers such as dioxane; esters such as methyl lactate, ethyl lactate (EL), methyl acetate, ethyl acetate, butyl acetate, methyl pyruvate, ethyl pyruvate, methyl methoxy propionate, and ethyl ethoxy propionate; and aromatic organic solvents such as anisole, ethyl benzyl ether, cresyl methyl ether, diphenyl ether, dibenzyl ether, phenetole, butyl phenyl ether, ethylbenzene, diethylbenzene, amylbenzene, isopropylbenzene, toluene, xylene, cymene, and mesitylene.

These organic solvents may be used alone or in the form of a mixed solvent of two or more kinds thereof.

Among these, propylene glycol monomethyl ether acetate (PGMEA), propylene glycol monomethyl ether (PGME), and EL are preferable.

Further, a mixed solvent obtained by mixing PGMEA with a polar solvent is also preferable. The blending ratio (mass ratio) thereof may be appropriately determined in consideration of the compatibility between PGMEA and the polar solvent, but is preferably in a range of 1:9 to 9:1 and more preferably in a range of 2:8 to 8:2.

More specifically, in a case where EL is blended as the polar solvent, the mass ratio of PGMEA:EL is preferably in a range of 1:9 to 9:1 and more preferably in a range of 2:8 to 8:2. Further, PGME is blended as the polar solvent, the mass ratio of PGMEA:PGME is preferably in a range of 1:9 to 9:1 and more preferably in a range of 2:8 to 8:2.

In addition to the solvents described above, a mixed solvent of y-butyrolactone and at least one selected from PGMEA, PGME, and EL is also preferable as the component (S). In this case, as the mixing ratio, the mass ratio between the former and the latter is preferably in a range of 70:30 to 95:5.

The amount of the organic solvent to be used can be appropriately set according to the coating film thickness at a concentration set such that a support such as a substrate can be coated with the organic solvent, and it is preferable that the organic solvent is used such that the solid content concentration in the resist composition is 25% by mass or greater. From the viewpoint of forming a thick-film resist film having a sufficiently large thickness, the organic solvent is used such that the solid content concentration in the resist composition is more preferably 30% by mass or greater and still more preferably 35% by mass or greater.

<Optional Component>

For the purpose of preventing deterioration in sensitivity and improving the resist pattern shape, the resist composition for forming a thick-film resist film of the present invention may contain, as an optional component (F) (hereinafter, also referred to as a “component (F)”) at least one compound selected from the group consisting of organic carboxylic acids, phosphorus oxo acids, and derivatives thereof.

As desired, miscible additives such as additive resins for improving the performance of the resist film, surfactants for improving the coatability, dissolution inhibitors, plasticizers, stabilizers, colorants, halation prevention agents, and dyes can be added to the resist composition for forming a thick-film resist film of the present invention, as appropriate.

Preferred examples of the organic carboxylic acids include acetic acid, malonic acid, citric acid, malic acid, succinic acid, benzoic acid, and salicylic acid.

Examples of the phosphorus oxo acids and derivatives thereof include phosphoric acid, phosphonic acid, and phosphinic acid. Among these, phosphonic acid is particularly preferable.

Examples of the phosphorus oxo acid derivatives include esters in which a hydrogen atom in the above-described oxo acids is substituted with a hydrocarbon group. Examples of the hydrocarbon group include an alkyl group having 1 to 5 carbon atoms and an aryl group having 6 to 15 carbon atoms.

Examples of the phosphoric acid derivatives include phosphoric acid esters such as di-n-butyl phosphate and diphenyl phosphate.

Examples of the phosphonic acid derivatives include phosphonic acid esters such as dimethyl phosphonate, di-n-butyl phosphonate, phenylphosphonic acid, diphenyl phosphonate, and dibenzyl phosphonate.

Examples of the phosphinic acid derivatives include phosphinic acid ester such as phenylphosphinic acid.

In the present invention, it is particularly preferable that the resist composition contains a dissolution inhibitor from the viewpoint that the effect of the present invention, that is, the effect of forming a thick-film resist pattern having a satisfactory shape is further improved. In a case where the dissolution inhibitor is used, a difference in solubility (dissolution contrast) between the exposed portion and the unexposed portion is improved, and the resolution and the resist pattern shape are improved. The dissolution inhibitor is not particularly limited, and can be appropriately selected from, for example, those that have been proposed in the related art as dissolution inhibitors for resist compositions for a KrF excimer laser and an ArF excimer laser.

Specific examples of the dissolution inhibitor include a compound in which some or all hydrogen atoms of the phenolic hydroxyl group in a polyhydric phenol compound containing two or more phenolic hydroxyl groups have been substituted with an acid dissociable dissolution inhibition group (a compound in which a phenolic hydroxyl group is protected by an acid dissociable dissolution inhibition group).

Examples of the acid dissociable dissolution inhibition group include the same groups as those which are exemplary examples in the section of the constitutional unit (a2).

Examples of the polyhydric phenol compound in a state where the phenolic hydroxyl group is not protected by an acid dissociable dissolution inhibition group includes a compound represented by Formula (f-1).

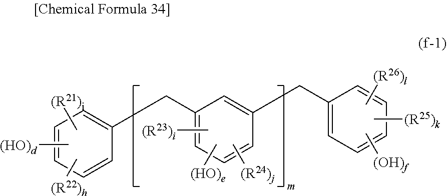

[In Formula (f-1), R²¹ to R²⁶ each independently represent an alkyl group having 1 to 10 carbon atoms or an aromatic hydrocarbon group, and the structure thereof may have hetero atoms; d and g each independently represent an integer of 1 or greater, h represents an integer of 0 or 1 or greater, and d+g+h is 5 or less; e represents an integer of 1 or greater, i and j each independently represent an integer of 0 or 1 or greater, e+i+j is 4 or less, f and k each independently represent an integer of 1 or greater, 1 represents an integer of 0 or 1 or greater, and f+k+1 is 5 or less; and m represents an integer of 1 to 20.]

The alkyl group as R²¹ to R²⁶ may be linear, branched, or cyclic, and a linear or branched lower alkyl group having 1 to 5 carbon atoms or a cyclic alkyl group having 5 to 6 carbon atoms is preferable.

The number of carbon atoms of the aromatic hydrocarbon group as R²¹ to R²⁶ is preferably in a range of 6 to 15, and examples thereof include a phenyl group, a tolyl group, a xylyl group, a mesityl group, a phenethyl group, and a naphthyl group.

The alkyl group or the aromatic hydrocarbon group may have hetero atoms such as an oxygen atom, a nitrogen atom, and a sulfur atom in the structure thereof.

Among these, it is preferable that all of R²¹ to R²⁶ represent a lower alkyl group having 1 to 5 carbon atoms.

d and g each independently represent an integer of 1 or greater and preferably 1 or 2, h represents 0 or 1 or greater and preferably an integer of lower than 2, and d+g+h is 5 or less.

e represents 1 or greater and preferably an integer of 1 or 2, i represents an integer of 0 or 1 or greater, j represents 0 or 1 or greater and preferably an integer of lower than 2, and e+i+j is 4 or less.

f and k each independently represent 1 or greater and preferably an integer of 1 or 2, 1 represents 0 or 1 or greater and preferably an integer of lower than 2, and f+k+1 is 5 or less. m represents 1 to 20 and preferably an integer of 2 to 10.

As the dissolution inhibitor, in Formula (f-1), a compound in which all hydrogen atoms of a phenolic hydroxyl group in a polyhydric phenol compound, in which R²¹ to R²⁶ each independently represent an alkyl group (methyl group) having one carbon atom; d and g represent 1, h represents 0; e, i, and j represent 1; f and k represent 1, 1 represents 0; and m represents 2, have been substituted with an acid dissociable dissolution inhibition group which is a chain-like tertiary alkoxycarbonylalkyl group is preferable.

The component (F) may be used alone or in combination of two or more kinds thereof.

From the viewpoints of the productivity and the handleability, the resist composition for forming a thick-film resist film of the present invention has preferably a low viscosity and more preferably, for example, a viscosity of less than 250 cP at 25° C. and 1 atm.

In a case where the viscosity thereof is greater than 250 cP, since the composition is unlikely to be uniformly diffused on the substrate, it is difficult to form a uniform film, and thus it is difficult to form a film having a desired film thickness.

<<Thick-Film Resist Film>>

The resist composition for forming a thick-film resist film of the present invention is used for forming a thick-film resist film having a film thickness of 8 to 18 μm on a support, and a resist pattern having a satisfactory shape can be formed in a case of a thick-film resist film having a film thickness of 18 μm or less. Further, the resist pattern formed on the thick-film resist film having a film thickness of 8 μm or greater can be used for various applications such as production of MEMS.

The film thickness of the thick-film resist film formed of the resist composition for forming a thick-film resist film of the present invention is preferably in a range of 8 to 18 μm and more preferably in a range of 10 to 17 μm.

The resist composition for forming a thick-film resist film of the present invention is preferably used in a thick-film resist laminate and a thick-film resist pattern forming method of the present invention described below.

<<Thick-Film Resist Laminate>>

The thick-film resist laminate of the present invention is obtained by laminating, on a support, a thick-film resist film having a film thickness of 8 to 18 μm, which is formed of the resist composition for forming a thick-film resist film of the present invention.

The support is not particularly limited and a known support of the related art can be used, and examples thereof include a substrate for an electronic component and a substrate on which a predetermined wiring pattern is formed. Examples of the substrate include a metal substrate such as silicon, silicon nitride, titanium, tantalum, palladium, titanium tungsten, copper, chromium, iron, aluminum, gold, or nickel, and a glass substrate. As the materials of the wiring pattern, copper, solder, chromium, aluminum, nickel, gold, or the like is used.

Further, as the support, a support in which an organic or inorganic antireflection film is formed on a surface of the above-described substrate (between the substrate and a coating layer of a positive-tone resist composition) can also be used.

The thick-film resist laminate can be produced according to a known method of the related art except for using the resist composition for forming a thick-film resist film of the present invention. For example, the thick-film resist laminate can be produced by coating the support with a solution of the resist composition so as to have a desired film thickness to form a coated film and performing a heat treatment (prebake (post applied bake (PAB) treatment) on the coated film to remove the organic solvent in the coated film.

The method of coating the support with the solution of the resist composition is not particularly limited, and a method such as a spin coating method, a slit coating method, a roll coating method, a screen printing method, or an applicator method can be employed.

The conditions for the prebake treatment after the support is coated with the resist composition for forming a thick-film resist film of the present invention vary depending on the kind of each component in the composition, the blending ratio, the coating film thickness, and the like, but the prebake treatment is performed typically under the conditions of 60° C. to 150° C. (preferably in a range of 90° C. to 150° C.) for 0.5 to 10 minutes (preferably in a range of 0.5 to 3 minutes).

The film thickness of the thick-film resist film in the thick-film resist laminate is as described above.

<<Thick-Film Resist Pattern Forming Method>>

A thick-film resist pattern forming method includes a step of forming a thick-film resist film having a film thickness of 8 to 18 μm using the resist composition for forming a thick-film resist film of the present invention, on a support; a step of selectively exposing the thick-film resist film; and a step of performing alkali development on the thick-film resist film to form a resist pattern.

In the present invention, the support is not particularly limited and a known support of the related art can be used, and examples thereof include a substrate for an electronic component and a substrate on which a predetermined wiring pattern is formed. More specific examples thereof include a metal substrate such as a silicon wafer, silica, silicon nitride, copper, chromium, iron, or aluminum, and a glass substrate. As the materials of the wiring pattern, copper, aluminum, nickel, or gold can be used.

Further, as the support, a support in which an inorganic and/or organic film is formed on the above-described substrate may be employed. As the inorganic film, an inorganic antireflection film (inorganic BARC) can be used. Examples of the organic film include an organic film such as an organic antireflection film (organic BARC) or a lower-layer organic film used for a multilayer resist method.

The wavelength to be used for exposure is not particularly limited and the exposure can be conducted using radiation such as an ArF excimer laser, a KrF excimer laser, an F₂ excimer laser, extreme ultraviolet rays (EUV), vacuum ultraviolet rays (VUV), electron beams (EB), X-rays, and soft X-rays. The resist pattern forming method of the present invention is highly useful for a KrF excimer laser, EB, and EUV and particularly useful for a KrF excimer laser.

The exposure of the photoresist film may be typical exposure (dry exposure) performed in air or an inert gas such as nitrogen or liquid immersion exposure (liquid immersion lithography).

In the alkali developing process, the alkali developing solution used for the developing treatment can be appropriately selected from known alkali developing solutions. Examples thereof include a 0.1 to 10 mass % tetramethylammonium hydroxide (TMAH) aqueous solution.

In the solvent developing process, the organic solvent contained in the organic developing solution used in the developing treatment can be appropriately selected from known organic solvents. Specific examples thereof include a polar solvent such as a ketone-based organic solvent, an ester-based organic solvent, an alcohol-based organic solvent, a nitrile-based organic solvent, an amide-based organic solvent, or an ether-based organic solvent, and a hydrocarbon-based organic solvent.

Known additives can be blended into the organic developing solution as desired. Examples of the additive include a surfactant. The surfactant is not particularly limited, and for example, an ionic or non-ionic fluorine-based and/or silicon-based surfactant can be used.

In a case where a surfactant is blended into the solution, the amount of the surfactant to be blended is typically in a range of 0.001% to 5% by mass, preferably in a range of 0.005% to 2% by mass, and more preferably in a range of 0.01% to 0.5% by mass with respect to the total amount of the organic developing solution.

The developing treatment can be performed according to a known developing method, and examples thereof include a method of immersing a support in a developing solution for a certain time (a dip method), a method of raising a developing solution on the surface of a support using the surface tension and maintaining the state for a certain time (a puddle method), a method of spraying a developing solution to the surface of a support (spray method), and a method of continuously ejecting a developing solution onto a support rotating at a certain rate while scanning a developing solution ejection nozzle at a certain rate (dynamic dispense method).

The resist pattern forming method of the present invention can be performed, for example, in the following manner.

First, a thick-film resist film is formed on the support. The present step can be performed according to the same method as that described in the method of producing the thick-film resist laminate.

Next, the formed thick-film resist film is selectively exposed (for example, the thick-film resist film is selectively exposed to KrF excimer laser light through a desired mask pattern using a KrF exposure device or the like), and PEB (post-exposure heating) is performed. The conditions for the PEB treatment vary depending on the kind of each component in the composition, the blending ratio, the coating film thickness, and the like, but the PEB treatment is performed typically under the conditions of 60° C. to 150° C. (preferably in a range of 90° C. to 150° C.) for 0.5 to 10 minutes (preferably in a range of 0.5 to 3 minutes).

Next, the thick-film resist laminate after the PEB treatment is subjected to the developing treatment using an alkali developing solution, for example, a 0.1 to 10 mass % tetramethylammonium hydroxide aqueous solution.

According to the present invention, a resist pattern having a satisfactory shape can be formed on a thick-film resist film having a film thickness of 8 to 18 km.

### EXAMPLES

Hereinafter, the present invention will be described in more detail with reference to examples and comparative example, but the present invention is not limited to these examples.

The materials used in the following examples and comparative examples are shown below.

[Component (A)]

A-1: a copolymer in which the molar ratio of x¹:y¹:z¹ is 70:15:15 in Formula (A-1)

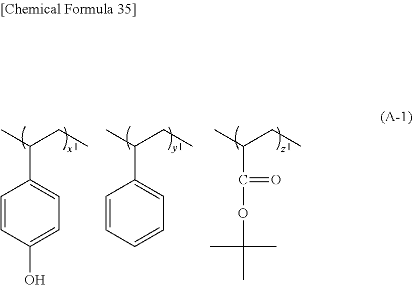

[Component (B)]

B-1 to B-5: compounds respectively represented by Formulae (B-1) to (B-5)

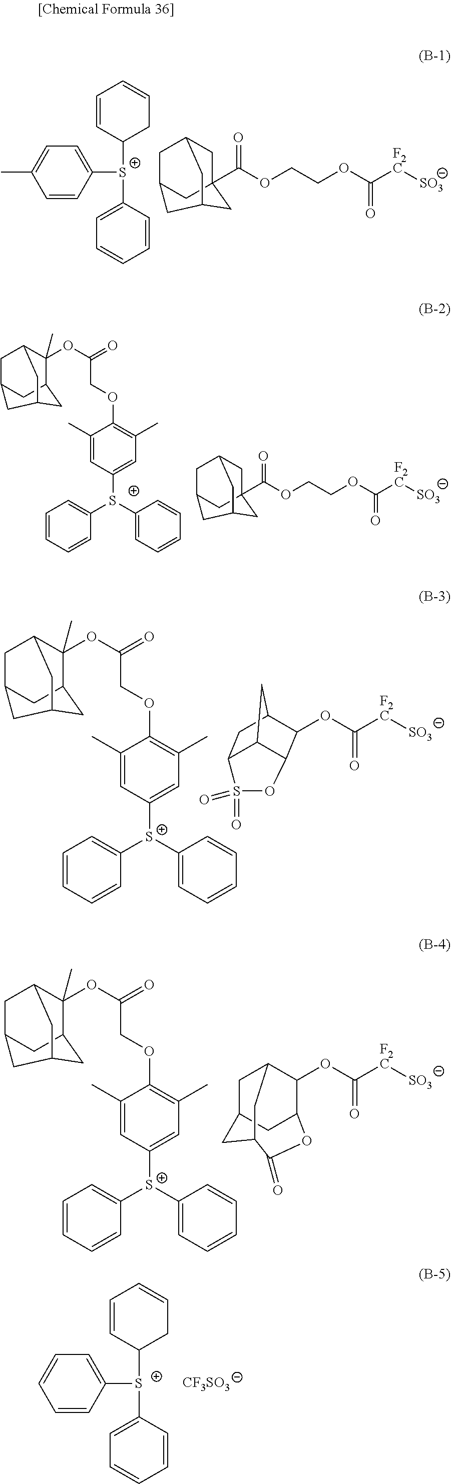

[Component (D)]

D-1: a compound represented by Formula (D-1)

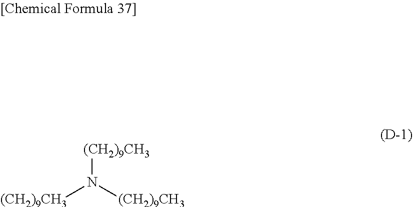

[Component (E)]

E-1 and E-2: compounds respectively represented by Formulae (E-1) and (E-2)

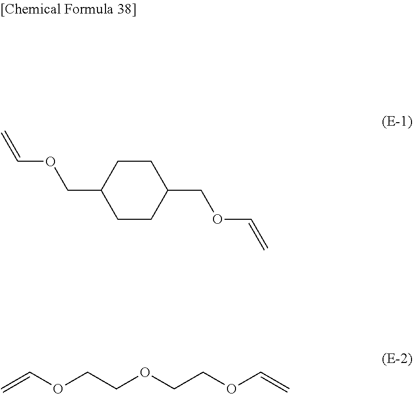

[Component (S)]

S-1: PGMEA

S-2: PGME

[Component (F)]

F-1: A Compound Represented by Formula (F-1)

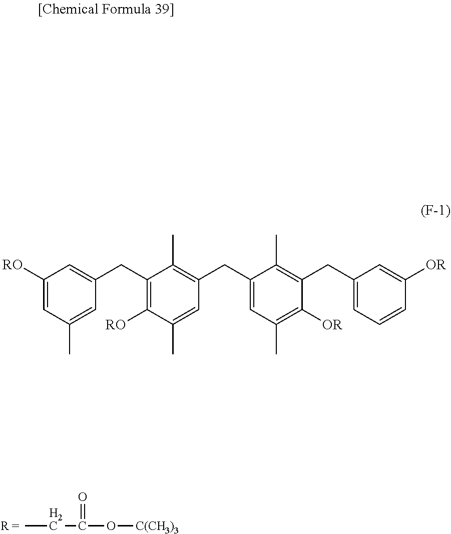

### Examples 1 to 10 and Comparative Examples 1 to 4

The respective components listed in Table 1 were mixed and dissolved, thereby preparing resist compositions.

In Table 1, the unit of the blending amount described in the parentheses indicates parts by mass of each component with respect to 100 parts by mass of the component (A).

TABLE 1

| | | Mass average | | | | | | | Solid content |
|---|---|---|---|---|---|---|---|---|---|
| | Component | molecular weight | Component | Component | Component | Component | Component | | concentration |
| | (A) | of component (A) | (B) | (D) | (E) | (F) | (S) | | (%) |
| Example 1 | A-1 | 8000 | B-1 | D-1 | E-1 | — | S-1 | S-2 | 38.5 |
| | [100] | | [0.5] | [0.03] | [5] | | [84] | [84] | |
| Example 2 | A-1 | 10000 | B-1 | D-1 | E-1 | — | S-1 | S-2 | 36.8 |
| | [100] | | [0.5] | [0.03] | [5] | | [91] | [91] | |
| Example 3 | A-1 | 15000 | B-1 | D-1 | E-1 | — | S-1 | S-2 | 35.2 |
| | [100] | | [0.5] | [0.03] | [5] | | [97] | [97] | |
| Example 4 | A-1 | 10000 | B-1 | D-1 | E-2 | — | S-1 | S-2 | 36.5 |
| | [100] | | [0.5] | [0.03] | [10] | | [96] | [96] | |
| Example 5 | A-1 | 10000 | B-2 | D-1 | E-1 | — | S-1 | S-2 | 36.5 |
| | [100] | | [0.7] | [0.03] | [5] | | [92] | [92] | |
| Example 6 | A-1 | 10000 | B-3 | D-1 | E-1 | — | S-1 | S-2 | 36.5 |
| | [100] | | [0.7] | [0.03] | [5] | | [92] | [92] | |
| Example 7 | A-1 | 10000 | B-4 | D-1 | E-1 | — | S-1 | S-2 | 36.5 |
| | [100] | | [0.7] | [0.03] | [5] | | [92] | [92] | |
| Example 8 | A-1 | 10000 | B-5 | D-1 | E-1 | — | S-1 | S-2 | 36.5 |
| | [100] | | [0.3] | [0.03] | [5] | | [92] | [92] | |
| Example 9 | A-1 | 10000 | B-1 | D-1 | E-1 | — | S-1 | S-2 | 36.5 |
| | [100] | | [0.5] | [0.03] | [3] | | [90] | [90] | |
| Example 10 | A-1 | 10000 | B-1 | D-1 | E-1 | — | S-1 | S-2 | 36.5 |
| | [100] | | [0.5] | [0.03] | [10] | | [96] | [96] | |
| Comparative | A-1 | 20000 | B-1 | D-1 | — | — | S-1 | S-2 | 32.8 |
| Example 1 | [100] | | [0.5] | [0.03] | | | [103] | [103] | |
| Comparative | A-1 | 10000 | B-1 | D-1 | — | — | S-1 | S-2 | 35.2 |
| Example 2 | [100] | | [0.5] | [0.03] | | | [93] | [93] | |
| Comparative | A-1 | 10000 | B-1 | D-1 | — | F-1 | S-1 | S-2 | 36.0 |
| Example 3 | [100] | | [0.5] | [0.03] | | [5] | [94] | [94] | |
| Comparative | A-1 | 10000 | B-1 | D-1 | E-1 | — | S-1 | S-2 | 24.0 |
| Example 4 | [100] | | [0.5] | [0.03] | [5] | | [167] | [167] | |

<Formation of Resist Pattern>

A 12-inch silicon wafer to which a hexamethyldisilazane (HMDS) treatment had been applied was coated with each composition in Table 1 using a spinner CLEAN TRACK ACT12 (manufactured by Tokyo Electron Limited), subjected to a post applied bake (PAB) treatment on a hot plate at 150° C. for 90 seconds, and dried, thereby forming a thick-film resist layer as listed in Table 2.

TABLE 2

| | Film thickness (μm) |
|---|---|
| Example 1 | 9.58 |
| Example 2 | 9.66 |
| Example 3 | 9.56 |
| Example 4 | 9.14 |
| Example 5 | 9.45 |
| Example 6 | 9.53 |
| Example 7 | 9.50 |
| Example 8 | 9.43 |
| Example 9 | 9.94 |
| Example 10 | 8.37 |
| Comparative | 9.56 |
| Example 1 | |
| Comparative | 9.60 |
| Example 2 | |
| Comparative | 9.61 |
| Example 3 | |
| Comparative | 1.93 |
| Example 4 | |

Next, the resist layer was selectively exposed through a binary mask using a KrF exposure device (wavelength of 248 nm) NSR-S210D (manufactured by Nikon Corporation; numerical aperture (NA)=0.55, σ=0.83). Thereafter, a post exposure bake (PEB) treatment was performed at 110° C. for 60 seconds. Next, solvent development was performed using a 2.38 mass % tetraammonium hydroxide (TMAH) aqueous solution (NMD-3) at 23° C. for 30 seconds, and a rinse treatment was performed.

Further, alkali development was performed twice using a 2.38 mass % tetramethylammonium hydroxide (TMAH) aqueous solution (NMD-3) at 23° C. for 35 seconds and 10 seconds respectively, and water rinse was performed using pure water for 15 seconds. In this manner, a resist pattern was formed.

<Evaluation of Crack Resistance>

A 12-inch silicon wafer to which a hexamethyldisilazane (HMDS) treatment had been applied was coated with each composition using a spinner CLEAN TRACK ACT12 and dried by being subjected to a bake treatment at 150° C. for 90 seconds, thereby forming a resist pattern. The patterned wafer was allowed to stand in a vacuum chamber for 3 minutes and observed with a CD-SEM (scanning electron microscope) CG4000 (manufactured by Hitachi, Ltd.), and the occurrence of cracks was evaluated based on the following evaluation standards. The results are listed in Table 3.

A: Cracks did not occur

B: Cracks partially occurred

C: Cracks occurred

TABLE 3

| | Evaluation of crack |
|---|---|
| | resistance |
| Example 1 | A |
| Example 2 | A |
| Example 3 | A |
| Example 4 | B |
| Example 5 | A |
| Example 6 | A |
| Example 7 | A |
| Example 8 | A |
| Example 9 | A |
| Example 10 | A |
| Comparative | A |
| Example 1 | |
| Comparative | C |
| Example 2 | |
| Comparative | C |
| Example 3 | |
| Comparative | A |
| Example 4 | |

As shown in the results described above, the resist pattern formed by using the resist composition of the present invention has an effect of excellent crack resistance.

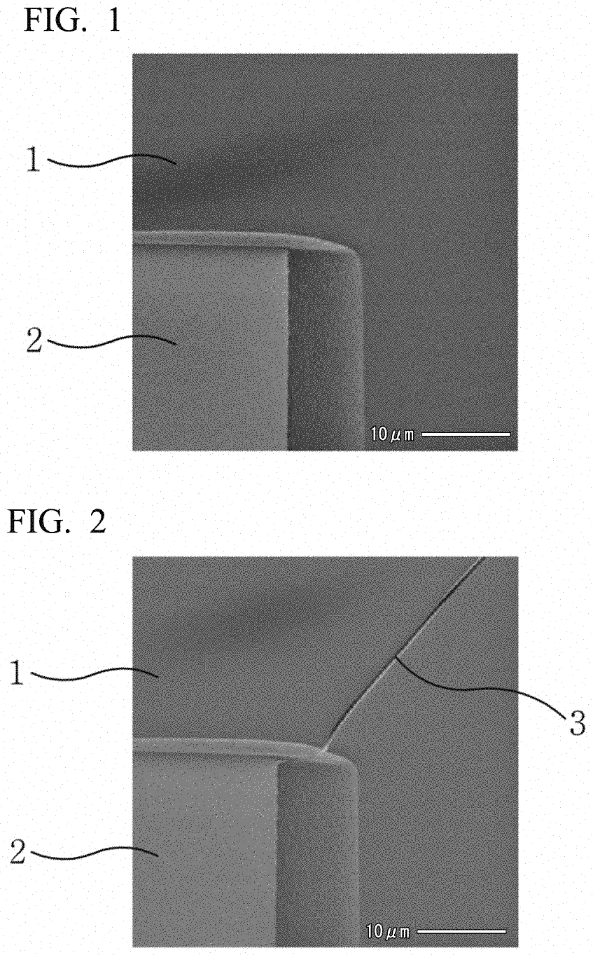

FIGS. 1 and 2 show the results of observing the resist pattern shapes formed by using the resist composition according to the present invention in photographs obtained by imaging the resist pattern shapes using a scanning electron microscope (SEM) CG4000 (manufactured by Hitachi, Ltd.).

As shown in FIG. 2, cracks were formed in the resist pattern formed by using the resist composition of Comparative Example 2. On the contrary, as shown in FIG. 1, cracks did not occur in the resist pattern formed by using the resist composition of Example 1 according to the present invention.

<Evaluation of Viscosity>

The viscosities of the compositions of Examples 1 to 11 and Comparative Examples 1 to 4 in Table 1 were measured such that the film thickness of 10 m was maintained at an optional rotation speed under the conditions of 25° C. at 1 atm using Stavinger viscometer (SVM3000, manufactured by Anton Paar GmbH).

The results are listed in Table 4.

TABLE 4

| | Viscosity (cP) |
|---|---|
| Example 1 | 202 |
| Example 2 | 215 |
| Example 3 | 235 |
| Example 4 | 215 |
| Example 5 | 215 |
| Example 6 | 215 |
| Example 7 | 215 |
| Example 8 | 215 |
| Example 9 | 215 |
| Example 10 | 215 |
| Comparative | 260 |
| Example 1 | |
| Comparative | 214 |
| Example 2 | |
| Comparative | 215 |
| Example 3 | |
| Comparative | — |
| Example 4 | |

As shown in the results described above, all the resist compositions of the present invention have a viscosity of less than 250 cP, which is a low viscosity, whereas the composition of Comparative Example 1 in which the average mass molecular weight of the base material component (A) is greater than 18000 has a viscosity of greater than 250 cP.

The viscosity of the composition of Comparative Example 4 was not measured because the solid content concentration of the resist composition was less than 25% by mass and the resist film thickness was not sufficiently large.

As examined described above, the evaluation results of the crack resistance and the viscosities of the compositions of Examples 1 to 11 and Comparative Examples 1 to 4 are collectively listed in Table 5. According to the present invention, since the resist composition contains a low-molecular-weight base material and a specific vinyl group-containing compound, and the solid content concentration of the resist composition is set to 25% by mass or greater, the crack resistance is improved and the viscosity decreases.

TABLE 5

| | | Mass average | | | |
|---|---|---|---|---|---|
| | Component | molecular weight | Component | Component | Component |
| | (A) | of component (A) | (B) | (D) | (E) |
| Example 1 | A-1 | 8000 | B-1 | D-1 | E-1 |
| | [100] | | [0.5] | [0.03] | [5] |
| Example 2 | A-1 | 10000 | B-1 | D-1 | E-1 |
| | [100] | | [0.5] | [0.03] | [5] |
| Example 3 | A-1 | 15000 | B-1 | D-1 | E-1 |
| | [100] | | [0.5] | [0.03] | [5] |
| Example 4 | A-1 | 10000 | B-1 | D-1 | E-2 |
| | [100] | | [0.5] | [0.03] | [10] |
| Example 5 | A-1 | 10000 | B-2 | D-1 | E-1 |
| | [100] | | [0.7] | [0.03] | [5] |
| Example 6 | A-1 | 10000 | B-3 | D-1 | E-1 |
| | [100] | | [0.7] | [0.03] | [5] |
| Example 7 | A-1 | 10000 | B-4 | D-1 | E-1 |
| | [100] | | [0.7] | [0.03] | [5] |
| Example 8 | A-1 | 10000 | B-5 | D-1 | E-1 |
| | [100] | | [0.3] | [0.03] | [5] |
| Example 9 | A-1 | 10000 | B-1 | D-1 | E-1 |
| | [100] | | [0.5] | [0.03] | [3] |
| Example 10 | A-1 | 10000 | B-1 | D-1 | E-1 |
| | [100] | | [0.5] | [0.03] | [10] |
| Comparative | A-1 | 20000 | B-1 | D-1 | — |
| Example 1 | [100] | | [0.5] | [0.03] | |
| Comparative | A-1 | 10000 | B-1 | D-1 | — |
| Example 2 | [100] | | [0.5] | [0.03] | |
| Comparative | A-1 | 10000 | B-1 | D-1 | — |
| Example 3 | [100] | | [0.5] | [0.03] | |
| Comparative | A-1 | 10000 | B-1 | D-1 | E-1 |
| Example 4 | [100] | | [0.5] | [0.03] | [5] |

| | | | | Solid content | Evaluation | |
|---|---|---|---|---|---|---|
| | Component | Component | | concentration | of crack | Viscosity |
| | (F) | (S) | | (%) | resistance | (cP) |
| Example 1 | — | S-1 | S-2 | >25 | A | <250 |
| | | [84] | [84] | | | |
| Example 2 | — | S-1 | S-2 | >25 | A | <250 |
| | | [91] | [91] | | | |
| Example 3 | — | S-1 | S-2 | >25 | A | <250 |
| | | [97] | [97] | | | |
| Example 4 | — | S-1 | S-2 | >25 | B | <250 |
| | | [96] | [96] | | | |
| Example 5 | — | S-1 | S-2 | >25 | A | <250 |
| | | [92] | [92] | | | |
| Example 6 | — | S-1 | S-2 | >25 | A | <250 |
| | | [92] | [92] | | | |
| Example 7 | — | S-1 | S-2 | >25 | A | <250 |
| | | [92] | [92] | | | |
| Example 8 | — | S-1 | S-2 | >25 | A | <250 |
| | | [92] | [92] | | | |
| Example 9 | — | S-1 | S-2 | >25 | A | <250 |
| | | [90] | [90] | | | |
| Example 10 | — | S-1 | S-2 | >25 | A | <250 |
| | | [96] | [96] | | | |
| Comparative | — | S-1 | S-2 | >25 | A | >250 |
| Example 1 | | [103] | [103] | | | |
| Comparative | — | S-1 | S-2 | >25 | C | <250 |
| Example 2 | | [93] | [93] | | | |
| Comparative | F-1 | S-1 | S-2 | >25 | C | <250 |
| Example 3 | [5] | [94] | [94] | | | |
| Comparative | — | S-1 | S-2 | <25 | A | — |
| Example 4 | | [167] | [167] | | | |

According to the present invention, it is possible to provide a resist composition for forming a thick-film resist film having excellent crack resistance and a low viscosity, a thick-film resist laminate, and a resist pattern forming method, by allowing the resist composition to contain a low-molecular-weight base material and a specific vinyl group-containing compound and setting the solid content concentration of the resist composition to be in a specific range.

While preferred embodiments of the invention have been described and illustrated above, it should be understood that these are exemplary of the invention and are not to be considered as limiting. Additions, omissions, substitutions, and other modifications can be made without departing from the scope of the invention. Accordingly, the invention is not to be considered as being limited by the foregoing description and is only limited by the scope of the appended claims.

### EXPLANATION OF REFERENCES

1: Photoresist
2: Exposed portion (Si substrate)
3: Crack

What is claimed is:

1. A resist composition which generates an acid upon light exposure and whose solubility in a developing solution is changed due to an action of an acid, the resist composition comprising:
a base material component (A) whose solubility in a developing solution is changed due to an action of an acid;
an acid generator component (B) which generates an acid upon light exposure;
an acid diffusion control agent component (D); and
a vinyl group-containing compound (E) represented by Formula (e-1),
wherein the base material component (A) has a mass average molecular weight of 8000 to 18000, and
the resist composition has a solid content concentration of 25% by mass or greater:
CH₂═CH—O—R²⁷—O—CH═CH₂ (e-1)
wherein R²⁷ represents a linear or branched alkylene group having 1 to 10 carbon atoms or a group represented by Formula (e-2), and R²⁷ may have a substituent and may also have an ether bond in a main chain; 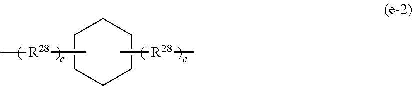
wherein R²⁸'s each independently represents a linear or branched alkylene group having 1 to 10 carbon atoms which may have a substituent, the alkylene group may have an ether bond in a main chain, and c's each independently represent 0 or 1.

2. The resist composition according to claim 1, wherein in Formula (e-1), R²⁷ represents —C₄H₈—, —C₂H₄OC₂H₄—, —C₂H₄OC₂H₄OC₂H₄—, or a group represented by Formula (e-2).

3. The resist composition according to claim 1, wherein in Formula (e-1), R²⁷ represents a group represented by Formula (e-2).

4. The resist composition according to claim 3, wherein in Formula (e-2), R²⁸ represents a methylene group, and each c's represent 1.

5. The resist composition according to claim 1, wherein the acid generator component (B) is a compound represented by Formula (b-1): 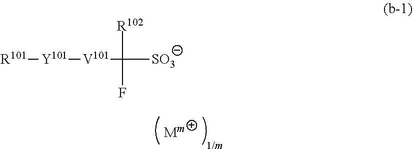
wherein each R^{101′}s independently represent a cyclic group which may have a substituent, a chain-like alkyl group which may have a substituent, or a chain-like alkenyl group which may have a substituent, R¹⁰² represents a fluorine atom or a fluorinated alkyl group having 1 to 5 carbon atoms, Y¹⁰¹ represents a divalent linking group having an oxygen atom, V¹⁰¹'s each independently represent a single bond, an alkylene group, or a fluorinated alkylene group, m represents an integer of 1 or greater, and M′^{m+} represents an m-valent onium cation.

6. The resist composition according to claim 1, wherein the resist composition has a solid content concentration of 30% by mass or greater.

7. A resist laminate comprising:
a support; and
a resist film formed of the resist composition according to claim 1 laminated on the support,
wherein the resist film has a film thickness of 8 to 18 μm.

8. A resist pattern forming method comprising:
forming a resist film having a film thickness of 8 to 18 μm using the resist composition according to claim 1 on a support;
selectively exposing the resist film; and
performing alkali development on the exposed resist film to form a resist pattern.
